(19) United States
(12) Patent Application Publication
(10) Pub. No.: US 2024/0122041 A1
(43) Pub. Date: Apr. 11, 2024

(54) DISPLAY DEVICE AND METHOD OF MANUFACTURING THE SAME

(71) Applicant: Samsung Display Co., LTD., Yongin-si (KR)

(72) Inventors: Swae Hyun KIM, Yongin-si (KR); Jeong Ho LEE, Yongin-si (KR); You Han MOON, Yongin-si (KR); Deok Hoi KIM, Yongin-si (KR); Ki Ryeol BAE, Yongin-si (KR); Min Su LEE, Yongin-si (KR)

(21) Appl. No.: 18/232,752

(22) Filed: Aug. 10, 2023

(30) Foreign Application Priority Data
Oct. 6, 2022 (KR) 10-2022-0128192
Oct. 17, 2022 (KR) 10-2022-0133282

(51) Int. Cl. H10K 59/80; H10K 59/12; H10K 59/124

(52) U.S. Cl. CPC H10K 59/8731; H10K 59/1201; H10K 59/124

(57) ABSTRACT

A display device and a method of manufacturing the same are provided. The display device comprises a substrate comprising a display area in which emission areas are arranged, a main non-display area around the display area, a hole area surrounded by the display area, and an additional non-display area between the hole area and the display area; a circuit layer; a light emitting element layer; a sealing layer; a through portion in the hole area and penetrating at least the substrate; and sealing auxiliary structures in the additional non-display area and sequentially surrounding the hole area. Each of the sealing auxiliary structures comprises a first undercut portion in which a first cover layer protrudes from a first main layer; and a second undercut portion in which a second cover layer protrudes from a second main layer.

### CROSS-REFERENCE TO RELATED APPLICATIONS

The present application claims priority to and the benefit of Korean Patent Application No. 10-2022-0128192, filed on Oct. 6, 2022, in the Korean Intellectual Property Office and the benefit of Korean Patent Application No. 10-2022-0133282, filed on Oct. 17, 2022, in the Korean Intellectual Property Office, the entire disclosure of each of which is incorporated herein by reference.

### BACKGROUND

### 1. Field

Aspects of some embodiments of the present disclosure relate to a display device and a method of manufacturing the same.

### 2. Description of the Related Art

As the information society develops, consumer demand for display devices for displaying images has increased in various forms. For example, display devices may be applied to, or incorporated into, various electronic devices such as smartphones, digital cameras, notebook computers, navigation devices, and smart televisions.

Display devices may include flat panel display devices such as liquid crystal display devices, field emission display devices, and light emitting display devices. Light emitting display devices may include an organic light emitting display device including an organic light emitting element, an inorganic light emitting display device including an inorganic light emitting element such as an inorganic semiconductor, and a micro- or nano-light emitting display device including a micro- or nano-light emitting element.

An organic light emitting display device generally displays images using a plurality of light emitting elements, each including a light emitting layer of an organic material. Because organic light emitting display devices implement images using self-light emitting elements as described above, it may have relatively higher performance than other display devices in terms of power consumption, response speed, luminous efficiency, luminance, and wide viewing angle.

The above information disclosed in this Background section is only for enhancement of understanding of the background and therefore the information discussed in this Background section does not necessarily constitute prior art.

### SUMMARY

A display device may include a through portion in a hole area surrounded by a display area.

In addition, in order to provide light emitting elements in the display area, the display device may include an anode of each emission area, a first common layer on the anode, a light emitting layer on the first common layer, a second common layer on the light emitting layers of the emission areas, and a cathode on the second common layer. That is, because the second common layer and the cathode are in the entire display area, they may also be arranged around the through portion.

When the second common layer of an organic material and the cathode of a metal material are arranged around the through portion, an oxygen or moisture permeation path may be generated around the through portion. Therefore, the life of light emitting elements adjacent to the through-portion may be rapidly shortened.

In addition, a separate mask process is added when the second common layer and the cathode around the through portion are partially removed to block the generation of the oxygen or moisture permeation path around the through portion.

Aspects of some embodiments of the present disclosure include a display device that may be capable of delaying or blocking the generation of an oxygen or moisture permeation path around a through portion without adding a separate mask process and a method of manufacturing the display device.

However, aspects of embodiments according to the present disclosure are not restricted to the one set forth herein. The above and other aspects of the present disclosure will become more apparent to one of ordinary skill in the art to which the present disclosure pertains by referencing the detailed description of the present disclosure given below.

According to some embodiments, a display device comprises a substrate comprising a display area in which emission areas are arranged, a main non-display area around the display area, a hole area surrounded by the display area, and an additional non-display area between the hole area and the display area; a circuit layer on the substrate and comprising pixel drivers respectively corresponding to the emission areas; a light emitting element layer on the circuit layer and comprising light emitting elements respectively corresponding to the emission areas; a sealing layer on the light emitting element layer; a through portion in the hole area and penetrating at least the substrate; and sealing auxiliary structures in the additional non-display area and sequentially surrounding the hole area. According to some embodiments, each of the sealing auxiliary structures comprises a first main layer; a first cover layer on the first main layer; a second main layer on the first cover layer; a second cover layer on the second main layer; a first undercut portion in which the first cover layer protrudes from the first main layer; and a second undercut portion in which the second cover layer protrudes from the second main layer.

According to some embodiments, the light emitting element layer comprises an anode on the circuit layer and corresponding to each of the emission areas; a pixel defining layer on the circuit layer, corresponding to a non-emission area around each of the emission areas, and covering edges of the anode; a first common layer on the anode; a light emitting layer on the first common layer; a second common layer on the pixel defining layer and the light emitting layer and corresponding to the display area; and a cathode on the second common layer and corresponding to the display area. According to some embodiments, each of the light emitting elements has a structure in which the light emitting layer is between the anode and the cathode. According to some embodiments, the second common layer and the cathode extend to the additional non-display area and are separated by the first undercut portion and the second undercut portion of each of the sealing auxiliary structures.

According to some embodiments, the circuit layer comprises a semiconductor layer on the substrate; a first conductive layer on a gate insulating layer covering the semiconductor layer; a second conductive layer on an interlayer insulating layer covering the first conductive layer; a third conductive layer on a first planarization layer covering the second conductive layer; and a second planarization covering the third conductive layer. According to some embodiments, the second conductive layer comprises the first main layer and the first cover layer. According to some embodiments, the third conductive layer comprises the second main layer and the second cover layer.

According to some embodiments, the additional non-display area comprises a sub-encapsulation area adjacent to the hole area and surrounding the hole area; and a wiring bypass area between the sub-encapsulation area and the display area. According to some embodiments, the circuit layer further comprises wirings electrically connected to the pixel drivers. According to some embodiments, some of the wirings intersecting the hole area and the additional non-display area bypass the hole area along edges of the hole area in the wiring bypass area. According to some embodiments, the first planarization layer and the second planarization layer extend to the wiring bypass area.

According to some embodiments, the display device further comprises a main dam portion comprising one or more main dams which are in a main dam area of the main non-display area adjacent to the display area and sequentially surround edges of the display area; and a sub-dam portion comprising one or more sub-dams which are in a sub-dam area of the sub-encapsulation area adjacent to the wiring bypass area and sequentially surround the hole area. According to some embodiments, the first planarization layer, the second planarization layer, and the pixel defining layer are spaced apart from the main dam area and the sub-dam area.

According to some embodiments, the sealing layer comprises a first inorganic layer covering the light emitting element layer and comprising an inorganic insulating material; an organic layer on the first inorganic layer and comprising an organic insulating material; and a second inorganic layer covering the organic layer and comprising the inorganic insulating material. According to some embodiments, the organic layer corresponds to an area between the main dam portion and the sub-dam portion and overlaps the light emitting element layer, and the first inorganic layer and the second inorganic layer contact each other in the main dam area and the sub-dam area.

According to some embodiments, the first inorganic layer contacts a portion of the first main layer exposed by the first undercut portion of each of the sealing auxiliary structures and contacts a portion of the second main layer exposed by the second undercut portion of each of the sealing auxiliary structures.

According to some embodiments, the display device further comprises an etch stop portion in an area between the sealing auxiliary structures. According to some embodiments, the sealing auxiliary structures and the etch stop portion are on the interlayer insulating layer.

According to some embodiments, the etch stop portion comprises a portion of the first main layer on the interlayer insulating layer.

According to some embodiments, each of the first main layer and the second main layer comprises at least one of aluminum (Al) or copper (Cu). According to some embodiments, each of the first cover layer and the second cover layer comprises at least one of titanium (Ti) or molybdenum (Mo).

According to some embodiments, the second conductive layer further comprises a first bottom layer between the interlayer insulating layer and the first main layer. According to some embodiments, the third conductive layer further comprises a second bottom layer between the first planarization layer and the second main layer. According to some embodiments, each of the sealing auxiliary structures further comprises the first bottom layer and the second bottom layer. According to some embodiments, the second bottom layer of each of the sealing auxiliary structures is between the first cover layer and the second main layer.

According to some embodiments, the etch stop portion comprises the first bottom layer on the interlayer insulating layer.

According to some embodiments, the etch stop portion further comprises a portion of the first main layer on the first bottom layer.

According to some embodiments, each of the first main layer and the second main layer comprises at least one of aluminum (Al) or copper (Cu). According to some embodiments, each of the first cover layer and the second cover layer comprises at least one of titanium (Ti) or molybdenum (Mo), and each of the first bottom layer. According to some embodiments, the second bottom layer comprises at least one of titanium (Ti) or molybdenum (Mo).

According to some embodiments, each of the one or more main dams and the one or more sub-dams has a structure in which two or more dam layers are stacked. According to some embodiments, the two or more dam layers comprise the same layer as two or more of the first planarization layer, the second planarization layer and the pixel defining layer, respectively.

According to some embodiments, a method of manufacturing a display device comprises preparing a substrate comprising a display area in which emission areas are arranged, a main non-display area arranged around the display area, a hole area surrounded by the display area, and an additional non-display area between the hole area and the display area; arranging a circuit layer, which comprises pixel drivers respectively corresponding to the emission areas, on the substrate; and arranging a light emitting element layer, which comprises light emitting elements respectively corresponding to the emission areas, on the circuit layer. According to some embodiments, the arranging of the circuit layer comprises arranging a semiconductor layer on the substrate; arranging a gate insulating layer, which covers the semiconductor layer, on the substrate; arranging a first conductive layer on the gate insulating layer; arranging an interlayer insulating layer, which covers the first conductive layer, on the gate insulating layer; arranging a second conductive layer comprising a first main layer and a first cover layer sequentially stacked on the interlayer insulating layer; arranging a first planarization layer, which corresponds to the display area and covers the second conductive layer, on the interlayer insulating layer; arranging a third conductive layer comprising a second main layer and a second cover layer sequentially stacked on the first planarization layer; arranging a second planarization layer, which corresponds to the display area and covers the third conductive layer, on the first planarization layer; and arranging, in the additional non-display area, multilayer structures, each comprising the first main layer and the first cover layer and the second main layer and the second cover layer on the first cover layer and sequentially surrounding the hole area. According to some embodiments, the arranging of the light emitting element layer comprises arranging an anode, which corresponds to each of the emission areas, on the second planarization layer. According to some embodiments, a first auxiliary material layer is provided in the arranging of the second conductive layer. According to some embodiments, the first auxiliary material layer is in the hole area and a portion of the additional non-display area and comprises the first main layer and the first cover layer. According to some embodiments, a second auxiliary material layer is provided in the arranging of the third conductive layer. According to some embodiments, the second auxiliary material layer is on the first auxiliary material layer and comprises the second main layer and the second cover layer. According to some embodiments, the arranging of the multilayer structures comprises a process of partially removing the first auxiliary material layer and the second auxiliary material layer. According to some embodiments, side surfaces of at least a portion of the first main layer and side surfaces of the second main layer of each of the multilayer structures in the additional non-display area are partially removed in the arranging of the anode, to transform the multilayer structures into sealing auxiliary structures. According to some embodiments, each of the multilayer structures comprises a first undercut portion in which the first cover layer protrudes from the first main layer; and a second undercut portion in which the second cover layer protrudes from the second main layer.

According to some embodiments, the arranging of the light emitting element layer further comprises arranging a pixel defining layer, which corresponds to a non-emission area around each of the emission areas and covers edges of the anode, on the second planarization layer; arranging a first common layer on the anode; arranging a light emitting layer on the first common layer; arranging a second common layer, which corresponds to the display area, on the pixel defining layer and the light emitting layer; and arranging a cathode, which corresponds to the display area, on the second common layer. In the arranging of the second common layer, the second common layer extends to the additional non-display area and is separated by the first undercut portion and the second undercut portion of each of the sealing auxiliary structures in the additional non-display area. According to some embodiments, in the arranging of the cathode, the cathode extends to the additional non-display area and is separated by the first undercut portion and the second undercut portion of each of the sealing auxiliary structures in the additional non-display area.

According to some embodiments, an etch stop portion corresponding to an area between the multilayer structures is further provided in the arranging of the multilayer structures.

According to some embodiments, the etch stop portion comprises another portion of the first main layer.

According to some embodiments, the second conductive layer further comprises a first bottom layer between the interlayer insulating layer and the first main layer in the arranging of the second conductive layer. According to some embodiments, the third conductive layer further comprises a second bottom layer between the first planarization layer and the second main layer in the arranging of the third conductive layer. According to some embodiments, the second bottom layer of the second auxiliary material layer is on the first cover layer of the first auxiliary material layer.

According to some embodiments, the etch stop portion comprises the first bottom layer.

According to some embodiments, the etch stop portion further comprises another portion of the first main layer.

According to some embodiments, the method further comprises after the arranging of the light emitting element layer, arranging a sealing layer on the light emitting element layer; and arranging a through portion corresponding to the hole area and penetrating at least the substrate. According to some embodiments, the arranging of the sealing layer comprises arranging a first inorganic layer which covers the light emitting element layer by stacking an inorganic insulating material on the light emitting element layer; arranging an organic layer, which comprises an organic insulating material and corresponds to the display area, on the first inorganic layer; and arranging a second inorganic layer which covers the organic layer by stacking the inorganic insulating material on the organic layer. In the arranging of the first inorganic layer, the first inorganic layer contacts a portion of the first main layer exposed by the first undercut portion of each of the sealing auxiliary structures and contacts a portion of the second main layer exposed by the second undercut portion of each of the sealing auxiliary structures.

According to some embodiments, a display device according to some embodiments includes a substrate including a display area, a main non-display area, a hole area and an additional non-display area, a circuit layer on the substrate, a light emitting element layer on the circuit layer, a sealing layer on the light emitting element layer, a through portion in the hole area and penetrating the substrate, and sealing auxiliary structures in the additional non-display area between the display area and the hole area and sequentially surrounding the through portion. According to some embodiments, each of the sealing auxiliary structures includes a first undercut portion and a second undercut portion. According to some embodiments, the first undercut portion is provided by a first cover layer protruding from a first main layer. According to some embodiments, the second undercut portion is provided by a second cover layer protruding from a second main layer on the first cover layer.

According to some embodiments, the light emitting element layer may include an anode and a pixel defining layer on the circuit layer, a first common layer on the anode, a light emitting layer on the first common layer, a second common layer on the light emitting layer and the pixel defining layer, and a cathode on the second common layer. According to some embodiments, the second common layer and the cathode may extend to the additional non-display area and may be separated by the first undercut portion and the second undercut portion of each of the sealing auxiliary structures in the additional non-display area.

According to some embodiments, the sealing layer may include a first inorganic layer on the light emitting element layer, an organic layer on the first inorganic layer, and a second inorganic layer covering the organic layer.

As described above, according to some embodiments, the second common layer and the cathode extending to the additional non-display area are separated by the first undercut portion and the second undercut portion of each of the sealing auxiliary structures.

Accordingly, the probability that the second common layer and the cathode in the additional non-display area will become an oxygen or moisture permeation path may be reduced.

In addition, a portion of the first main layer may be exposed by the first undercut portion of each of the sealing auxiliary structures without being covered with the second common layer and the cathode extending to the additional non-display area. In addition, a portion of the second main layer may be exposed by the second undercut portion of each of the sealing auxiliary structures without being covered with the second common layer and the cathode extending to the additional non-display area.

Therefore, even if the second common layer and the cathode extend to the additional non-display area due to the exclusion of a separate mask process, the first inorganic layer may contact a portion of the first main layer exposed by the first undercut portion of each of the sealing auxiliary structures and may contact a portion of the second main layer exposed by the second undercut portion of each of the sealing auxiliary structures.

Accordingly, because the first inorganic layer contacts each of the first main layer and the second main layer, a sealing structure formed by bonding between inorganic materials may be provided around the through portion. Therefore, even if a separate mask process is not added, the generation of the oxygen or moisture permeation path around the through portion may be blocked or delayed.

The characteristics of embodiments according to the present disclosure are not limited to the aforementioned effects, and various other characteristics are included in the present specification.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to some embodiments;

FIG. 2 is a plan view of the display device of FIG. 1;

FIG. 3 is a cross-sectional view taken along the line A-A′ of FIG. 2;

FIG. 4 is a plan view of a main area and a sub-area of the display device of FIG. 1;

FIG. 5 is a layout view illustrating an example of emission areas arranged in portion B of FIG. 4;

FIG. 6 is an equivalent circuit diagram of a pixel driver according to some embodiments;

FIG. 7 is a plan view of two pixel drivers according to some embodiments;

FIG. 8 is a plan view of a semiconductor layer and a first conductive layer of FIG. 7;

FIG. 9 is a plan view of the semiconductor layer, the first conductive layer, and a second conductive layer of FIG. 7;

FIG. 10 is a plan view of a third conductive layer of FIG. 7;

FIG. 11 is a cross-sectional view taken along the line E-E′ of FIG. 7;

FIG. 12 is an enlarged view of the portion F of FIG. 11 according to some embodiments;

FIG. 13 is an enlarged view of the portion G of FIG. 11 according to some embodiments;

FIG. 14 is a cross-sectional view taken along the line C-C′ of FIG. 4 according to some embodiments;

FIG. 15 is a layout view of the portion D of FIG. 4 according to some embodiments;

FIG. 16 is a cross-sectional view taken along the line H-H′ of FIG. 15 according to some embodiments;

FIG. 17 is an enlarged view of sealing auxiliary structures and etch stop portions in portion I of FIG. 16;

FIG. 18 is an enlarged view of the portion I of FIG. 16;

FIG. 19 is an enlarged view of the portion F of FIG. 11 according to some embodiments;

FIG. 20 is an enlarged view of the portion G of FIG. 11 according to some embodiments;

FIG. 21 is a cross-sectional view taken along the line H-H′ of FIG. 15 according to some embodiments;

FIG. 22 is an enlarged view of the portion J of FIG. 21;

FIG. 23 is a cross-sectional view taken along the line H-H′ of FIG. 15 according to some embodiments;

FIG. 24 is an enlarged view of the portion K of FIG. 23;

FIG. 25 is a flowchart illustrating a method of manufacturing a display device according to some embodiments;

FIG. 26 is a flowchart illustrating an operation of placing a circuit layer in FIG. 25;

FIG. 27 is a flowchart illustrating an operation of placing a light emitting element layer in FIG. 25; and

FIGS. 28 through 45 are process diagrams showing the operations illustrated in FIGS. 25, 26 and 27.

### DETAILED DESCRIPTION

Aspects of some embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, aspects of some embodiments of the present disclosure will be described in more detail with reference to the accompanying drawings.

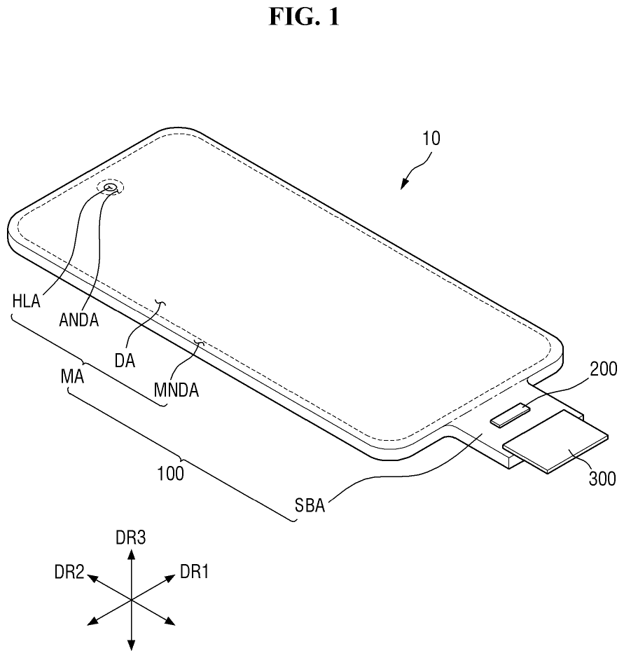

FIG. 1 is a perspective view of a display device 10 according to some embodiments.

Referring to FIG. 1, the display device 10 is a device for displaying moving images (e.g., video images) or still images (e.g., static images). The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards and Internet of things (IoT) devices.

The display device 10 may be a light emitting display device such as an organic light emitting display device using an organic light emitting diode, a quantum dot light emitting display device including a quantum dot light emitting layer, an inorganic light emitting display device including an inorganic semiconductor, or a micro- or nano-light emitting display device using a micro- or nano-light emitting diode. An embodiment where the display device 10 is an organic light emitting display device will be mainly described below, but aspects of embodiments of the present disclosure are also applicable to a display device including an organic insulating material, an organic light emitting material, and a metal material.

The display device 10 may be formed flat, but embodiments according to the present disclosure are not limited thereto. For example, the display device 10 may include curved portions formed at left and right ends and having a constant or varying curvature. In addition, the display device 10 may be formed to be flexible so that it can be curved, bent, folded, or rolled.

The display device 10 may include a display panel 100, a display driving circuit 200, and a circuit board 300.

The display panel 100 may include a main area MA including a display area DA in which an image is displayed and a sub-area SBA protruding from a side of the main area MA.

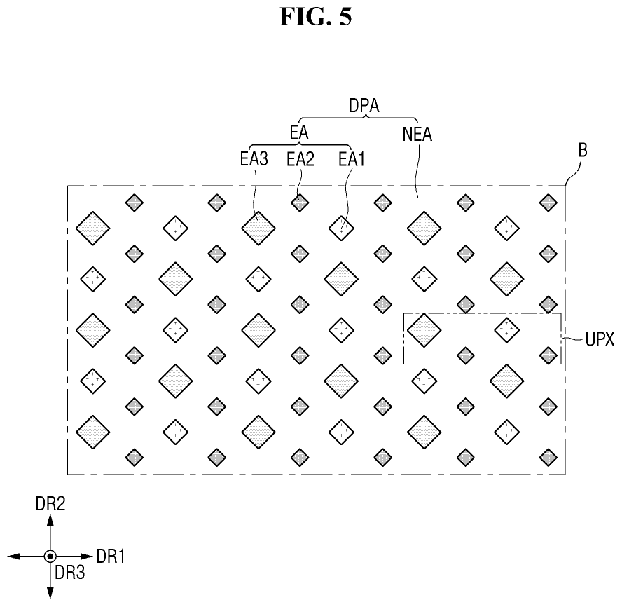

The main area MA includes the display area DA, a main non-display area MNDA arranged around the display area DA, a hole area HLA surrounded by the display area DA, and an additional non-display area ANDA between the hole area HLA and the display areas DA. Emission areas EA (see FIG. 5) are arranged in the display area DA.

That is, the display device 10 may include the display area DA in which the emission areas EA (see FIG. 5) for displaying an image are arranged, the main non-display area MNDA arranged around the display area DA, the hole area HLA surrounded by the display area DA, and the additional non-display area ANDA located between the hole area HLA and the display area DA.

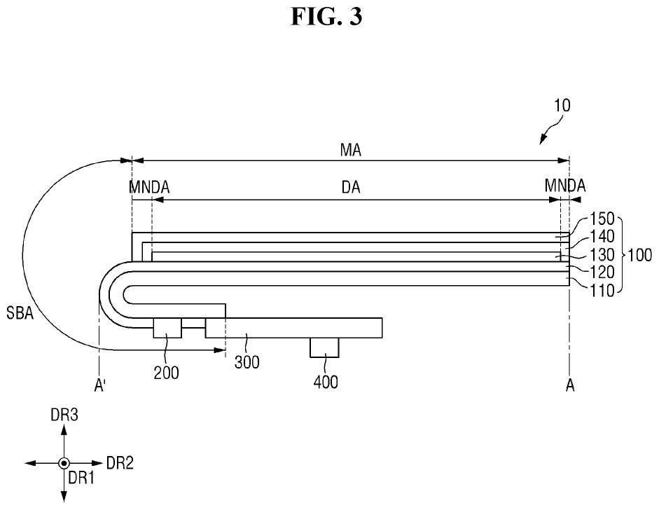

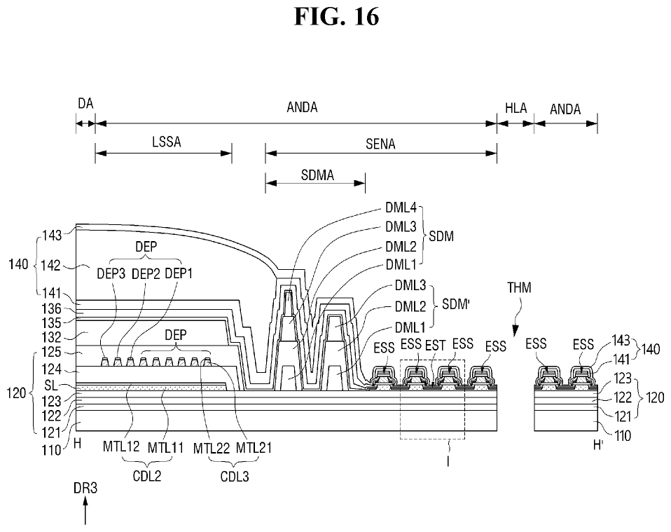

The display device 10 may further include a through portion THM (see FIG. 16) located in the hole area HLA and penetrating at least a substrate 110 (see FIG. 3) of the display panel 100. The through portion THM may overlap at least a portion of a functional module located on the outside of the display panel 100 and may be provided as a path for inputting sensing information of the functional module or a path for outputting sound of the functional module.

For example, the functional module may be arranged to overlap the through portion THM and an area around the through portion THM on a rear surface of the display panel 100 or may be located within the through portion THM.

For example, the functional module may include a camera module for capturing or recognizing an image corresponding to the front of the display device 10, a face recognition sensor module for detecting a user's face, a pupil recognition sensor module for detecting a user's eyes, an acceleration sensor module and a geomagnetic sensor module for judging the movement of the display device 10, a proximity sensor module and an infrared sensor module for detecting proximity to the front of the display device 10, an illuminance sensor module for measuring an external brightness level, etc.

The sub-area SBA may be an area protruding from a side of the main non-display area MNDA of the main area MA in a second direction DR2.

The display driving circuit 200 may be mounted on the sub-area SBA, and the circuit board 300 may be attached to the sub-area SBA.

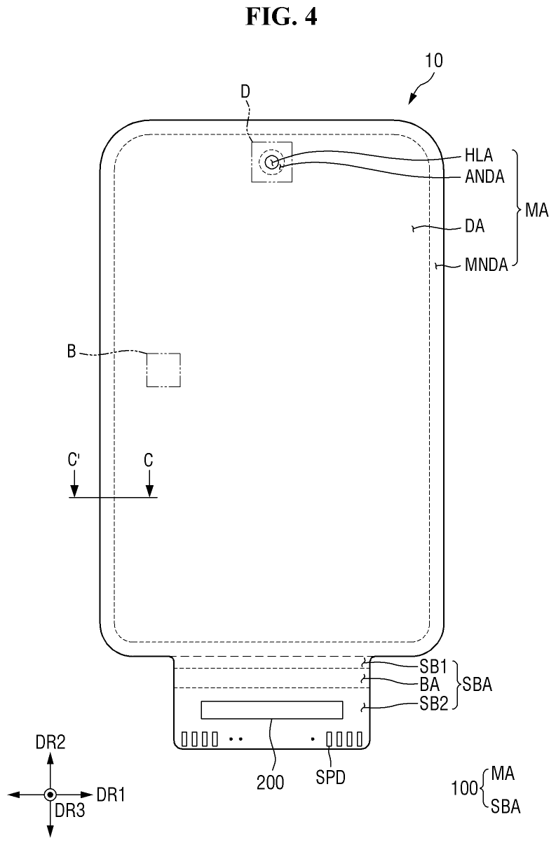

The display driving circuit 200 may be provided as an integrated circuit and mounted on a second sub-area SB2 (see FIG. 4) by a chip on glass (COG) method, a chip on plastic (COP) method, or an ultrasonic bonding method. However, embodiments according to the present disclosure are not limited thereto. For example, the display driving circuit 200 may also be mounted on the circuit board 300 by a chip on film (COF) method or may be embedded as a part of the display panel 100.

The circuit board 300 may be attached to the second sub-area SB2 using an anisotropic conductive film or a low-resistance, high-reliability material such as SAP and may be electrically connected to signal pads SPD (see FIG. 4) of the second sub-area SB2.

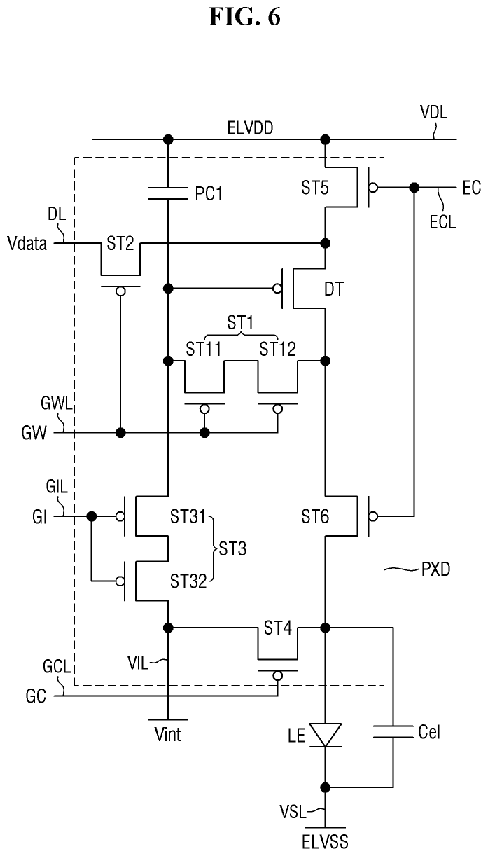

The circuit board 300 may supply digital video data, timing signals, and driving voltages to pixel drivers PXD (see FIG. 6) located in the display area DA or the display driving circuit 200 of the sub-area SBA.

The circuit board 300 may be a flexible printed circuit board, a printed circuit board, or a flexible film such as a chip on film.

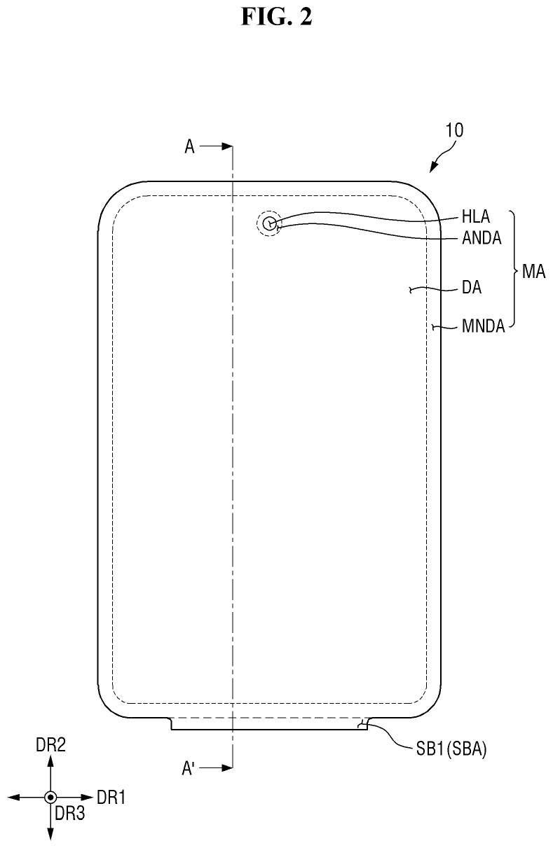

FIG. 2 is a plan view of the display device 10 of FIG. 1. FIG. 3 is a cross-sectional view taken along the line A-A′ of FIG. 2.

Referring to FIG. 2, a portion of the sub-area SBA may be bent. Accordingly, the display driving circuit 200 located in the sub-area SBA and the circuit board 300 attached to the sub-area SBA may be located on the rear surface of the display panel 100.

Referring to FIG. 3, the display panel 100 of the display device 10 includes the substrate 110, a circuit layer 120 located on the substrate 110, a light emitting element layer 130 located on the circuit layer 120, and a sealing layer 140 located on the light emitting element layer 130.

The substrate 110 includes the display area DA in which the emission areas EA are arranged, the main non-display area MNDA located around (e.g., in a periphery or outside a footprint of) the display area DA, the hole area HLA surrounded by the display area DA, and the additional non-display area ANDA between the hole area HLA and the display area DA.

The substrate 110 may include the main area MA and the sub-area SBA. The main area MA of the substrate 110 includes the display area DA, the main non-display area MNDA, the hole area HLA, and the additional non-display area ANDA.

The substrate 110 may be made of an insulating material such as polymer resin. For example, the substrate 110 may be made of polyimide. The substrate 110 may be a flexible substrate that can be bent, folded, or rolled.

The circuit layer 120 includes the pixel drivers PXD corresponding to the emission areas EA, respectively.

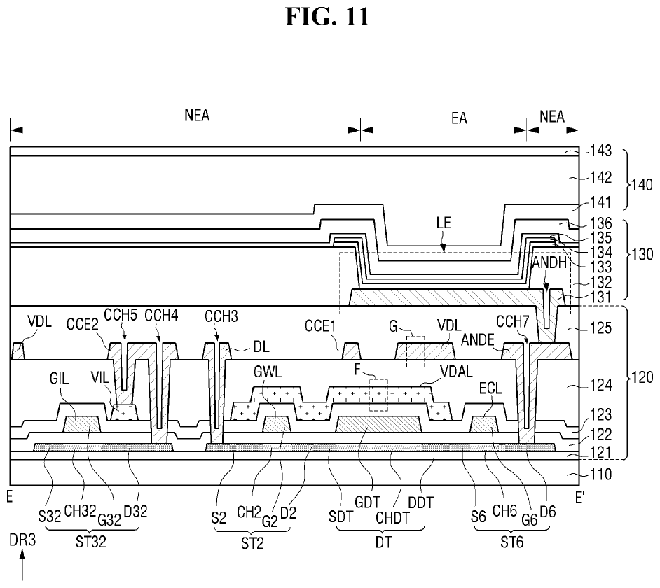

The light emitting element layer 130 may be located on the circuit layer 120 in the display area DA. The light emitting element layer 130 includes light emitting elements LE (see FIGS. 6 and 11) respectively corresponding to the emission areas EA. The light emitting elements LE of the light emitting element layer 130 may be electrically connected to the pixel drivers PXD of the circuit layer 120, respectively.

In addition, the display device 10 further includes the through portion THM located in the hole area HLA and penetrating at least the substrate 110. That is, the through portion THM may penetrate the display panel 100 of the hole area HLA.

The sealing layer 140 is located on the light emitting element layer 130. The sealing layer 140 may contact the circuit layer 120 in the main non-display area MNDA.

The sealing layer 140 is designed to protect the light emitting element layer 130 from permeation of oxygen or moisture. The sealing layer 140 may have a structure in which at least one inorganic layer and at least one organic layer are stacked.

In addition, the display device 10 may further include a sensor electrode layer 150 located on the sealing layer 140.

The sensor electrode layer 150 may be located on the sealing layer 140 in the main area MA. The sensor electrode layer 150 may include touch electrodes for sensing a touch of a person or an object.

The display device 10 may further include a cover window located on the sensor electrode layer 150. The cover window may be attached onto the sensor electrode layer 150 by a transparent adhesive member such as an optically clear adhesive (OCA) film or an optically clear resin (OCR). The cover window may be an inorganic material such as glass or may be an organic material such as plastic or a polymer material. The cover window may protect the sensor electrode layer 150, the sealing layer 140, the light emitting element layer 130, and the circuit layer 120 from electrical and physical impact on a display surface.

In addition, the display device 10 may further include an anti-reflection member located between the sensor electrode layer 150 and the cover window. The anti-reflection member may be a polarizing film or a color filter. The anti-reflection member may block external light reflected by the sensor electrode layer 150, the sealing layer 140, the light emitting element layer 130, the circuit layer 120, and interfaces between them, thereby preventing a reduction in visibility of an image of the display device 10.

The display device 10 may further include a touch driving circuit 400 for driving the sensor electrode layer 150.

The touch driving circuit 400 may be provided as an integrated circuit. The touch driving circuit 400 may be mounted on the circuit board 300 and thus electrically connected to the sensor electrode layer 150.

Alternatively, like the display driving circuit 200, the touch driving circuit 400 may be mounted on the sub-area SBA of the substrate 110.

The touch driving circuit 400 may transmit a touch driving signal to a plurality of driving electrodes included in the sensor electrode layer 150, receive touch sensing signals of a plurality of touch nodes through a plurality of sensing electrodes, respectively, and detect amounts of charge change in mutual capacitance based on the touch sensing signals.

That is, the touch driving circuit 400 may determine or detect whether a user's touch or proximity has occurred based on the touch sensing signal of each of the touch nodes. The user's touch indicates that an object such as the user's finger or a pen directly touches a front surface of the display device 10. The user's proximity indicates that an object such as the user's finger or a pen hovers above the front surface of the display device 10.

FIG. 4 is a plan view of the main area MA and the sub-area SBA of the display device 10 of FIG. 1.

The display device 10 may include the main area MA which includes the display area DA emitting light for image display and the sub-area SBA which protrudes from a side of the main area MA.

The main area MA may include the display area DA in which the emission areas EA (see FIG. 5) are arranged, the main non-display area MNDA arranged around the display area DA, the hole area HLA surrounded by the display area DA, and the additional non-display area ANDA between the hole area HLA and the display area DA.

The display area DA may be shaped like a rectangular plane having short sides in a first direction DR1 and long sides in the second direction DR2 intersecting the first direction DR1. Each corner where a short side extending in the first direction DR1 meets a long side extending in the second direction DR2 may be rounded with a predetermined curvature or may be right-angled. The planar shape of the display area DA is not limited to a quadrilateral shape but may also be another polygonal shape, a circular shape, or an oval shape.

The display area DA may occupy most of the main area MA. The display area DA may be located in a center of the main area MA.

The main non-display area MNDA may neighbor the display area DA and may be located outside edges of the display area DA. That is, the main non-display area MNDA may be an area outside the display area DA. The main non-display area MNDA may surround the display area DA. The main non-display area MNDA may be an edge area of the main area MA.

The sub-area SBA may protrude from a side of the main area MA in the second direction DR2. A length of the sub-area SBA in the first direction DR1 may be smaller than a length of the main area MA in the second direction DR2. The length of the sub-area SBA in the first direction DR1 may be smaller than a length of the main area MA in the first direction DR1 or may be substantially the same as the length of the main area MA in the first direction DR1.

The sub-area SBA may include a bending area BA which is transformed into a bent shape and a first sub-area SB1 and the second sub-area SB2 which contact both sides of the bending area BA.

The first sub-area SB1 is an area located between the main area MA and the bending area BA. A side of the first sub-area SB1 may contact the main non-display area MNDA of the main area MA, and the other side of the first sub-area SB1 may contact the bending area BA.

The second sub-area SB2 is an area spaced apart from the main area MA with the bending area BA interposed between them and an area located on the rear surface of the display panel 100 due to the bending area BA transformed into a bent shape. That is, the second sub-area SB2 may overlap the main area MA in a thickness direction DR3 of the display panel 100 due to the bending area BA transformed into a bent shape.

A side of the second sub-area SB2 may contact the bending area BA. The other side of the second sub-area SB2 may contact a portion of an edge of the substrate 110 (see FIG. 3).

The signal pads SPD and the display driving circuit 200 may be located in the second sub-area SB2.

The display driving circuit 200 may generate signals and voltages for driving the pixel drivers PD of the display area DA.

The circuit board 300 may be attached to the signal pads SPD of the second sub-area SB2 and electrically connected to the signal pads SPD.

The hole area HLA may be located adjacent to an edge of the display area DA.

Although one circular hole area HLA is illustrated in FIGS. 1, 2 and 4, the shape of the hole area HLA according to some embodiments is not limited to a circular shape, and the shape of the hole area HLA may have any suitable shape. For example, according to some embodiments, the hole area HLA may also be provided in a polygonal shape such as a triangle or a square or in an oval shape. The display device 10 according to some embodiments may also include two or more hole areas HLA.

The additional non-display area ANDA is an area between the hole area HLA and the display area DA and may be located outside the rim of the hole area HLA. That is, the additional non-display area ANDA is an area outside the hole area HLA and may surround the hole area HLA.

The additional non-display area ANDA may have a shape similar to that of the hole area HLA. However, the present disclosure is not limited thereto, and the additional non-display area ANDA according to some embodiments may also have a shape different from that of the hole area HLA.

FIG. 5 is a layout view illustrating an example of the emission areas EA arranged in portion B of FIG. 4.

Referring to FIG. 5, the display area DA may include the emission areas EA and a non-emission area NEA between the emission areas EA.

Two adjacent emission areas EA among the emission areas EA may neighbor each other in the first direction DR1 or the second direction DR2.

Each of the emission areas EA may be a unit that is driven individually to display light of any one of two or more different colors with a predetermined luminance.

For example, the emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color.

For example, the first color may be red in a wavelength band of approximately 600 to approximately 750 nm, the second color may be green in a wavelength band of approximately 480 to approximately 560 nm, and the third color may be blue in a wavelength band of approximately 370 to approximately 460 nm. However, this is only an example, and the wavelength bands of the first color, the second color and the third color according to some embodiments of the present specification are not limited thereto.

Because the emission areas EA include the first emission areas EA1, the second emission areas EA2 and the third emission areas EA3, unit pixels UPX, each including a combination of the first through third emission areas EA1 through EA3 adjacent to each other among the emission areas EA may be provided.

Each of the unit pixels UPX may be a unit for individually displaying various colors including white. That is, light of various colors displayed in each unit pixel UPX may be realized as a mixture of light emitted from two or more emission areas EA included in each unit pixel UPX.

In FIG. 5, the first emission areas EA1 and the third emission areas EA3 alternate in the first direction DR1 and the second direction DR2, and the second emission areas EA2 are located side by side with each other and located adjacent to the first emission areas EA1 and the third emission areas EA3 in diagonal directions intersecting the first direction DR1 and the second direction DR2. In this case, each of the unit pixels UPX may include one first emission area EA1 and one third emission area EA3 neighboring each other in the first direction DR1 or the second direction DR2 and two second emission areas EA2 neighboring the first emission area EA1 and the third emission area EA3 in the diagonal directions.

However, this is only an example, and the arrangement of the emission areas EA according to some embodiments is not limited to that illustrated in FIG. 5.

FIG. 6 is an equivalent circuit diagram of a pixel driver PXD according to some embodiments.

As described above, the circuit layer 120 of the display device 10 may include the pixel drivers PXD respectively corresponding to the emission areas EA and respectively electrically connected to the light emitting elements LE of the light emitting element layer 130.

The circuit layer 120 may include a data line DL transmitting a data signal Vdata to each of the pixel drivers PXD, a first power line VDL transmitting first power ELVDD to each of the pixel drivers PXD, and an initialization voltage line VIL transmitting an initialization voltage Vint to each of the pixel drivers PXD.

The circuit layer 120 may include a scan write line GWL transmitting a scan write signal GW to each of the pixel drivers PXD, a scan initialization line GIL transmitting a scan initialization signal GI to each of the pixel drivers PXD, an emission control line ECL transmitting an emission control signal EC to each of the pixel drivers PXD, and a gate control line GCL transmitting a gate control signal GC to each of the pixel drivers PXD.

One of the pixel drivers PXD may include two or more transistors ST1 through ST6 in addition to a driving transistor DT that generates a driving current for driving a light emitting element LE electrically connected to the pixel driver PXD and may include at least one capacitor PC1.

An anode of the light emitting element LE may be electrically connected to the pixel driver PXD, and a cathode of the light emitting element LE may be electrically connected to a second power line VSL that supplies second driving power ELVSS having a voltage level lower than that of the first power ELVDD.

The light emitting element LE may be an organic light emitting diode having a light emitting layer made of an organic light emitting material. Alternatively, the light emitting element LE may be an inorganic light emitting element having a light emitting layer made of an inorganic semiconductor. Alternatively, the light emitting element LE may be a quantum dot light emitting element having a quantum dot light emitting layer. Alternatively, the light emitting element LE may be a micro-light emitting diode.

A capacitor Cel connected in parallel to the light emitting element LE represents a parasitic capacitance between the anode and the cathode.

The driving transistor DT is connected in series to the light emitting element LE between the first power line VDL and the second power line VSL. That is, a first electrode (e.g., a source electrode) of the driving transistor DT may be connected to the first power line VDL through a fifth transistor ST5, and a second electrode (e.g., a drain electrode) of the driving transistor DT may be connected to the anode of the light emitting element LE through a sixth transistor ST6.

In addition, the first electrode of the driving transistor DT may be connected to the data line DL through a second transistor ST2.

A gate electrode of the driving transistor DT may be connected to the first power line VDL through a first capacitor PC1. That is, the first capacitor PC1 may be connected between the gate electrode of the driving transistor DT and the first power line VDL.

Accordingly, the potential of the gate electrode of the driving transistor DT may be maintained at the first power ELVDD of the first power line VDL.

Therefore, when the data signal Vdata of the data line DL is transmitted to the first electrode of the driving transistor DT through the second transistor ST2 that is turned on, corresponding to a difference between the first power ELVDD and the data signal Vdata may be generated between the gate electrode of the driving transistor DT and the first electrode of the driving transistor DT.

Here, when the voltage difference between the gate electrode of the driving transistor DT and the first electrode of the driving transistor DT, that is, a gate-source voltage difference is equal to or greater than a threshold voltage, the driving transistor DT may be turned on.

Then, when the fifth transistor ST5 and the sixth transistor ST6 are turned on, the driving transistor DT may generate a drain-source current corresponding to the data signal Vdata. The drain-source current of the driving transistor DT may be supplied as a driving current of the light emitting element LE.

Accordingly, the light emitting element LE may emit light having a luminance corresponding to the data signal Vdata.

The second transistor ST2 may be connected between the first electrode of the driving transistor DT and the data line DL.

A first transistor ST1 may be connected between the gate electrode of the driving transistor DT and the second electrode of the driving transistor DT.

The first transistor ST1 may include a plurality of sub-transistors connected in series. For example, the first transistor ST1 may include a first sub-transistor ST11 and a second sub-transistor ST12.

A first electrode of the first sub-transistor ST11 may be connected to the gate electrode of the driving transistor DT, a second electrode of the first sub-transistor ST11 may be connected to a first electrode of the second sub-transistor ST12, and a second electrode of the second sub-transistor ST12 may be connected to the second electrode of the driving transistor DT.

Accordingly, it may be possible to prevent or reduce instances of the potential of the gate electrode of the driving transistor DT being changed due to a leakage current caused by the first transistor ST1 that is not turned on.

A gate electrode of each of the second transistor ST2, the first sub-transistor ST11 and the second sub-transistor ST12 may be connected to the scan write line GWL.

Accordingly, when the scan write signal GW is received through the scan write line GWL, the second transistor ST2, the first sub-transistor ST11, and the second sub-transistor ST12 may be turned on.

Here, the data signal Vdata may be transmitted to the first electrode of the driving transistor DT through the turned-on second transistor ST2.

In addition, the gate electrode of the driving transistor DT may have the same potential as the second electrode of the driving transistor DT through the turned-on first sub-transistor ST11 and second sub-transistor ST12.

Accordingly, the driving transistor DT may be turned on.

A third transistor ST3 may be connected between the gate electrode of the driving transistor DT and the initialization voltage line VIL.

The third transistor ST3 may include a plurality of sub-transistors connected in series. For example, the third transistor ST3 may include a third sub-transistor ST31 and a fourth sub-transistor ST32.

A first electrode of the third sub-transistor ST31 may be connected to the gate electrode of the driving transistor DT, a second electrode of the third sub-transistor ST31 may be connected to a first electrode of the fourth sub-transistor ST32, and a second electrode of the fourth sub-transistor ST32 may be connected to the initialization voltage line VIL.

Accordingly, it may be possible to prevent or reduce instances of the potential of the gate electrode of the driving transistor DT being changed due to a leakage current caused by the third transistor ST3 that is not turned on.

A gate electrode of each of the third sub-transistor ST31 and the fourth sub-transistor ST32 may be connected to the scan initialization line GIL.

Accordingly, when the scan initialization signal GI is received through the scan initialization line GIL, the third sub-transistor ST31 and the fourth sub-transistor ST32 may be turned on so that the potential of the gate electrode of the driving transistor DT is initialized to the initialization voltage Vint of the initialization voltage line VIL.

A fourth transistor ST4 may be connected between the anode of the light emitting element LE and the initialization voltage line VIL.

A gate electrode of the fourth transistor ST4 may be connected to the gate control line GCL.

Accordingly, when the gate control signal GC is received through the gate control line GCL, the fourth transistor ST4 may be turned on.

Here, the potential of the anode of the light emitting element LE may be initialized to the initialization voltage Vint of the initialization voltage line VIL through the turned-on fourth transistor ST4.

Accordingly, the light emitting element LE may be prevented from being driven by a current remaining in the anode.

The fifth transistor ST5 may be connected between the first electrode of the driving transistor DT and the first power line VDL.

The sixth transistor ST6 may be connected between the second electrode of the driving transistor DT and the anode of the light emitting element LE.

A gate electrode of each of the fifth transistor ST5 and the sixth transistor ST6 may be connected to the emission control line ECL.

Accordingly, when the emission control signal EC is received through the emission control line ECL, the fifth transistor ST5 and the sixth transistor ST6 may be turned on so that the drain-source current of the driving transistor DT is supplied as the driving current of the element LE.

In FIG. 6, the driving transistor DT and the first through sixth transistors ST1 through ST6 included in the pixel driver PXD are all N-type metal oxide semiconductor field effect transistors (MOSFETs). However, it should be noted that the pixel driver PXD of the embodiments are not limited to the illustration of FIG. 6. That is, at least one of the driving transistor DT and the first through sixth transistors ST1 through ST6 included in the pixel driver PXD according to some embodiments may also be a P-type MOSFET.

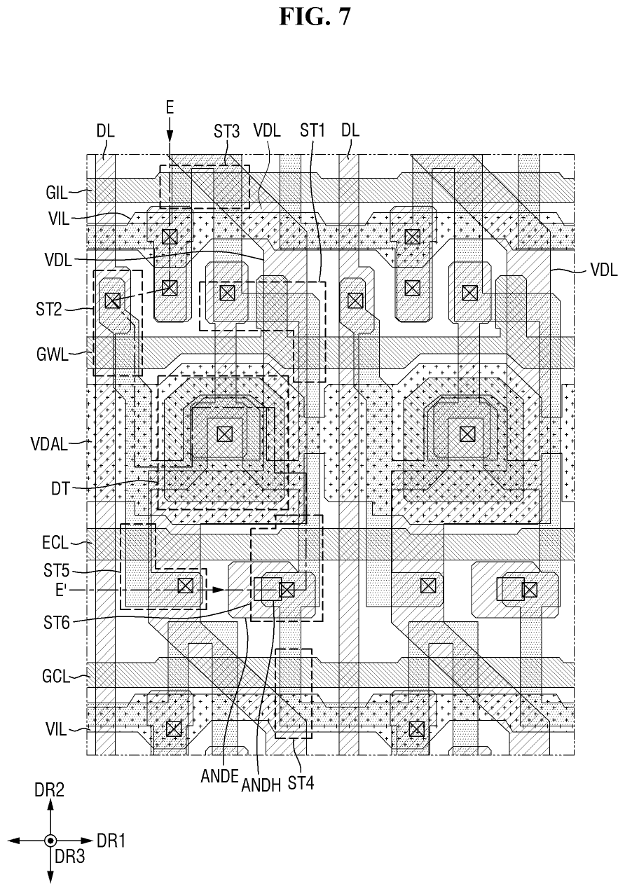

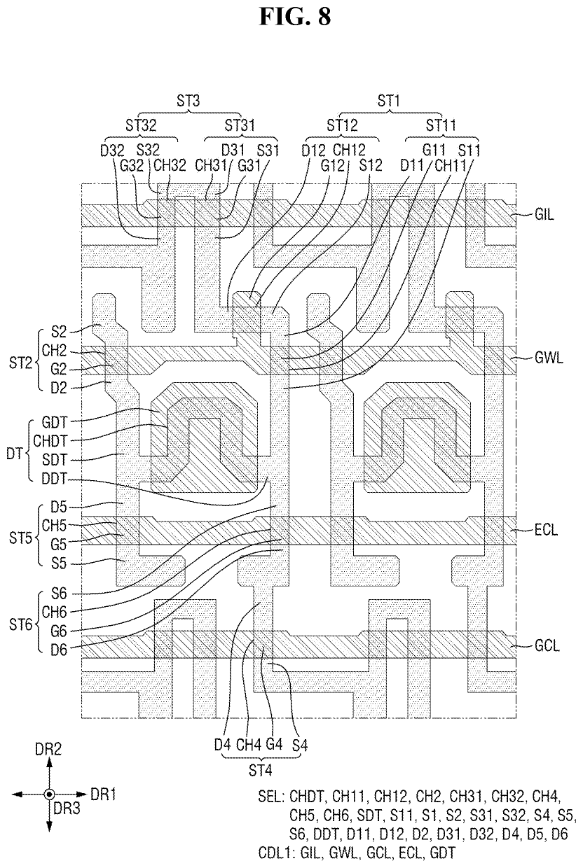

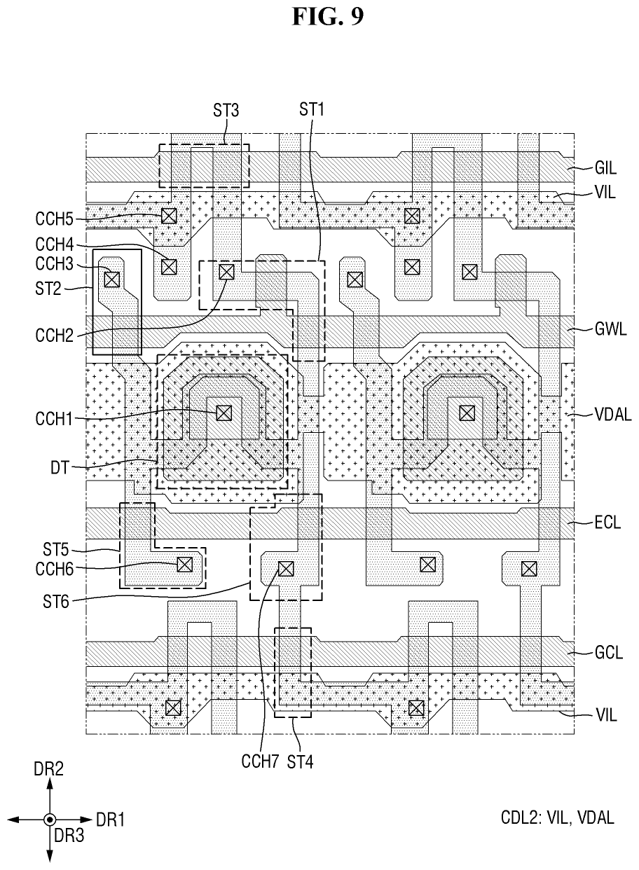

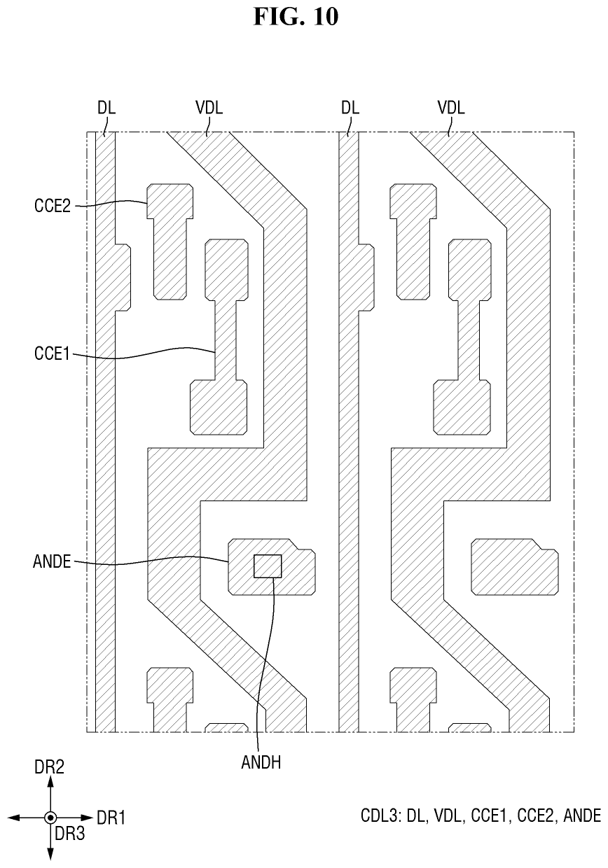

FIG. 7 is a plan view of two pixel drivers PXD according to some embodiments. FIG. 8 is a plan view of a semiconductor layer SEL and a first conductive layer CDL1 of FIG. 7. FIG. 9 is a plan view of the semiconductor layer SEL, the first conductive layer CDL1, and a second conductive layer CDL2 of FIG. 7. FIG. 10 is a plan view of a third conductive layer CDL3 of FIG. 7. FIG. 11 is a cross-sectional view taken along the line E-E′ of FIG. 7.

Referring to FIG. 7, a pixel driver PXD of the display device 10 according to some embodiments may include a driving transistor DT and first through sixth transistors ST1 through ST6.

The circuit layer 120 may include scan lines extending in the first direction DR1. The scan lines may include a scan write line GWL, a scan initialization line GIL, an emission control line ECL, and a gate control line GCL.

An initialization voltage line VIL may be made of a different conductive layer from the scan write line GWL, the scan initialization line GIL, the emission control line ECL and the gate control line GCL and may extend in the first direction DR1.

The circuit layer 120 may include data lines DL and first power lines VDL extending in the second direction DR2. The data lines DL and the first power lines VDL may be made of a different conductive layer from the scan write line GWL, the scan initialization line GIL, the emission control line ECL, and the gate control line GCL.

The circuit layer 120 may further include a first power auxiliary line VDAL made of the same conductive layer as the initialization voltage line VIL, extending in the first direction DR1, and electrically connected to the first power lines VDL.

Referring to FIG. 8, the semiconductor layer SEL may include a channel CHDT, a first electrode SDT and a second electrode DDT of the driving transistor DT and a channel CH11, CH12, CH2, CH31, CH32, CH4, CH5 or CH6, a first electrode S11, S12, S2, S31, S32, S4, S5 or S6 and a second electrode D11, D12, D2, D31, D32, D4, D5 or D6 of each of the first through sixth transistors ST1 through ST6.

The first conductive layer CDL1 may include a gate electrode GDT of the driving transistor DT, the scan write line GWL, the scan initialization line GIL, the emission control line ECL, and the gate control line GCL. The scan write line GWL, the scan initialization line GIL, the emission control line ECL, and the gate control line GCL extend in the first direction DR1.

The semiconductor layer SEL may be made of any one of polysilicon, amorphous silicon, and an oxide semiconductor.

The semiconductor layer SEL excluding portions overlapping the first conductive layer CDL1 (GDT, GWL, GIL, ECL and GCL), that is, excluding the channels CH11, CH12, CH2, CH31, CH32, CH4, CH5 and CH6 of the transistors DT and ST1 through ST6 may be made conductive.

The first conductive layer CDL1 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

A gate electrode G11 of a first sub-transistor ST11, a gate electrode G12 of a second sub-transistor ST12, and a gate electrode G2 of the second transistor ST2 may be different portions of the scan write line GWL.

A gate electrode G31 of a third sub-transistor ST31 and a gate electrode G32 of a fourth sub-transistor ST32 may be different portions of the scan initialization line GIL.

A gate electrode G4 of the fourth transistor ST4 may be a portion of the gate control line GCL.

A gate electrode G5 of the fifth transistor ST5 and a gate electrode G6 of the sixth transistor ST6 may be different portions of the emission control line ECL.

The channel CHDT of the driving transistor DT overlaps the gate electrode GDT of the driving transistor DT, and both ends of the channel CHDT of the driving transistor DT are connected to the first electrode SDT of the driving transistor DT and the second electrode DDT of the driving transistor DT, respectively.

The first electrode SDT of the driving transistor DT may be connected to the second electrode D2 of the second transistor ST2 and the second electrode D5 of the fifth transistor ST5.

The second electrode DDT of the driving transistor DT may be connected to the first electrode S11 of the first sub-transistor ST11 and the second electrode D6 of the sixth transistor ST6.

The first transistor ST1 may include the first sub-transistor ST11 and the second sub-transistor ST12 connected in series.

The channel CH11 of the first sub-transistor ST11 overlaps the gate electrode G11 of the first sub-transistor ST11 which is a portion of the scan write line GWL, and both ends of the channel CH11 of the first sub-transistor ST11 are connected to the first electrode S11 of the first sub-transistor ST11 and the second electrode D11 of the first sub-transistor ST11, respectively.

The second electrode D11 of the first sub-transistor ST11 may be connected to the first electrode S12 of the second sub-transistor ST12.

The channel CH12 of the second sub-transistor ST12 overlaps the gate electrode G12 of the second sub-transistor ST12, which is a portion of the scan write line GWL, and both ends of the channel CH12 of the second sub-transistor ST12 are connected to the first electrode S12 of the second sub-transistor ST12 and the second electrode D12 of the second sub-transistor ST12, respectively.

The second electrode D12 of the second sub-transistor ST12 may be connected to the first electrode S31 of the third sub-transistor ST31.

The channel CH2 of the second transistor ST2 overlaps the gate electrode G2 of the second transistor ST2 which is a portion of the scan write line GWL, and both ends of the channel CH2 of the second transistor ST2 are connected to the first electrode S2 of the second transistor ST2 and the second electrode D2 of the second transistor ST2.

The third transistor ST3 may include the third sub-transistor ST31 and the fourth sub-transistor ST32 connected in series.

The channel CH31 of the third sub-transistor ST31 overlaps the gate electrode G31 of the third sub-transistor ST31 which is a portion of the scan initialization line GIL, and both ends of the channel CH31 of the third sub-transistor ST31 are connected to the source electrode S31 of the third sub-transistor ST31 and the drain electrode D31 of the third sub-transistor ST31, respectively.

The drain electrode D31 of the third sub-transistor ST31 may be connected to the source electrode S32 of the fourth sub-transistor ST32.

The channel CH32 of the fourth sub-transistor ST32 overlaps the gate electrode G32 of the fourth sub-transistor ST32 which is a part of the scan initialization line GIL, and both ends of the channel CH32 of the fourth sub-transistor ST32 are connected to the source electrode S32 of the fourth sub-transistor ST32 and the drain electrode D32 of the fourth sub-transistor ST32, respectively.

The channel CH4 of the fourth transistor ST4 overlaps the gate electrode G4 of the fourth transistor ST4 which is a portion of a bias control line BCL, and both ends of the channel CH4 of the fourth transistor ST4 are connected to the first electrode S4 of the fourth transistor ST4 and the second electrode D4 of the fourth transistor ST4, respectively.

The second electrode D4 of the fourth transistor ST4 may be connected to the second electrode D6 of the sixth transistor ST6.

The channel CH5 of the fifth transistor ST5 overlaps the gate electrode G5 of the fifth transistor ST5 which is a portion of the emission control line ECL, and both ends of the channel CH5 of the fifth transistor ST5 are connected to the first electrode S5 of the fifth transistor ST5 and the second electrode D5 of the fifth transistor ST5, respectively.

The channel CH6 of the sixth transistor ST6 overlaps the gate electrode G6 of the sixth transistor ST6 which is a portion of the emission control line ECL, and both ends of the channel CH6 of the sixth transistor ST6 are connected to the first electrode S6 of the sixth transistor ST6 and the second electrode D6 of the sixth transistor ST6, respectively.

Referring to FIG. 9, the second conductive layer CDL2 may include the initialization voltage line VIL and the first power auxiliary line VDAL. The initialization voltage line VIL and the first power auxiliary line VDAL may extend in the first direction DR1.

The second conductive layer CDL2 may be a multilayer made of two or more of molybdenum (Mo), aluminum (Al), chromium (Cr), gold (Au), titanium (Ti), nickel (Ni), neodymium (Nd), and copper (Cu).

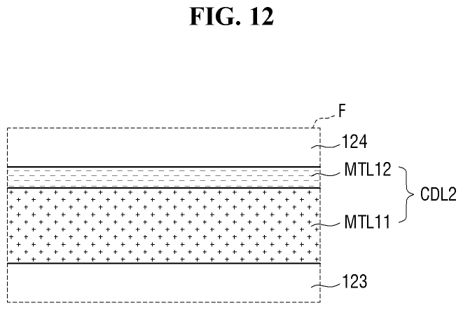

That is, the second conductive layer CDL2 may have a multilayer structure including a first main layer MTL11 (see FIG. 12) made of a metal material having relatively low resistance and a first cover layer MTL12 located on the first main layer MTL11 and made of a different metal material from the first main layer MTL11.

The first cover layer MTL12 may be made of a metal material that can block diffusion of the metal material of the first main layer MTL11 to the surrounding insulating material. For example, the first cover layer MTL12 may include titanium (Ti).

Because the second conductive layer CDL2 includes the first main layer MTL11 having relatively low resistance as described above, it may have lower resistance than the first conductive layer CDL1.

A portion of the first power auxiliary line VDAL may overlap the gate electrode GDT of the driving transistor DT.

Accordingly, a first capacitor PC1 may be provided by an overlap area between a first power sub-line VDSBL and the gate electrode GDT of the driving transistor DT.

The circuit layer 120 may include first through seventh connection contact holes CCH1 through CCH7 penetrating at least one of a gate insulating layer 122 (see FIG. 11) covering the semiconductor layer SEL, an interlayer insulating layer 123 (see FIG. 11) covering the first conductive layer CDL1, and a first planarization layer 124 (see FIG. 11) covering the second conductive layer CDL2.

The first connection contact hole CCH1 overlaps the gate electrode GDT of the driving transistor DT.

The second connection contact hole CCH2 overlaps a contact point (D12 and S31 of FIG. 8) between the first transistor ST1 and the third transistor ST3.

The third connection contact hole CCH3 overlaps the first electrode S2 of the second transistor ST2.

The fourth connection contact hole CCH4 overlaps the second electrode D32 (see FIG. 8) of the fourth sub-transistor ST32 (see FIG. 8) of the third transistor ST3.

The fifth connection contact hole CCH5 overlaps the initialization voltage line VIL.

The sixth connection contact hole CCH6 overlaps the first electrode S5 (see FIG. 8) of the fifth transistor ST5.

The seventh connection contact hole CCH7 overlaps a contact point (D4 and D6 of FIG. 8) between the fourth transistor ST4 and the sixth transistor ST6.

As illustrated in FIG. 11, the third connection contact hole CCH3, the fourth connection contact hole CCH4 and the seventh connection contact hole CCH7 overlapping the semiconductor layer SEL among the first through seventh connection contact holes CCH1 through CCH7 may penetrate the first planarization layer 124, the interlayer insulating layer 123, and the gate insulating layer 122 to expose the semiconductor layer SEL. Likewise, the second connection contact hole CCH2 and the sixth connection contact hole CCH6 overlapping the semiconductor layer SEL among the first through seventh connection contact holes CCH1 through CCH7 may penetrate the first planarization layer 124, the interlayer insulating layer 123, and the gate insulating layer 122 to expose the semiconductor layer SEL.

The first connection contact hole CCH1 may penetrate the first planarization layer 124 and the interlayer insulating layer 123 to expose the gate electrode GDT of the driving transistor DT made of the first conductive layer CDL1.

The fifth connection contact hole CCH5 may penetrate the first planarization layer 124 to expose the initialization voltage line VIL made of the second conductive layer CDL2.

Referring to FIG. 10, the third conductive layer CDL3 may include the data lines DL, the first power lines VDL, a first connection electrode CCE1, a second connection electrode CCE2, and an anode connection electrode ANDE.

The data lines DL and the first power lines VDL extend in the second direction DR2.

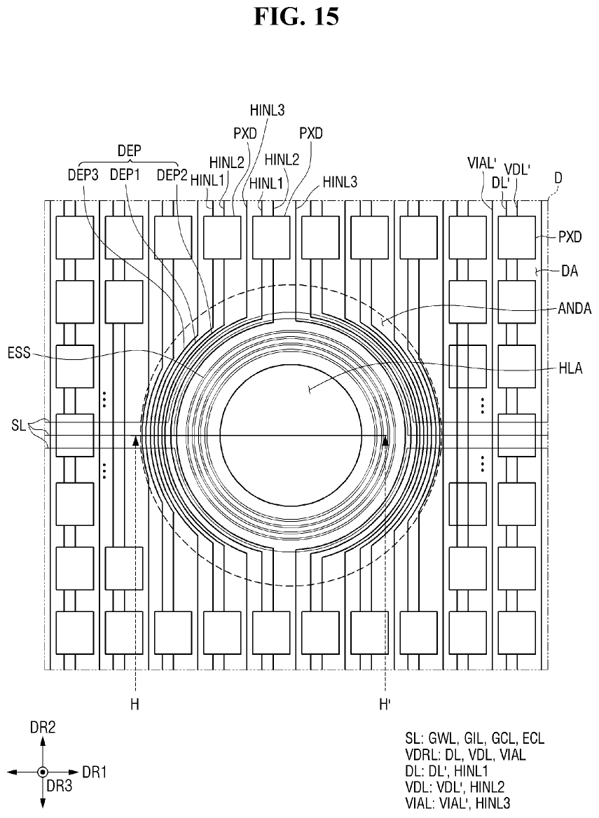

Alternatively, according to some embodiments, the third conductive layer CDL3 may further include an initialization voltage auxiliary line VIAL (see FIG. 15) extending in the second direction DR2. The initialization voltage auxiliary line VIAL may be spaced apart from the data lines DL and the first power lines VDL in the first direction DR1 and may extend in the second direction DR2. The initialization voltage auxiliary line VIAL may be electrically connected to the initialization voltage line VIL through a predetermined connection contact hole penetrating the first planarization layer 124.

The third conductive layer CDL3 may be a multilayer made of two or more of molybdenum (Mo), aluminum (Al), chromium (Cr), gold (Au), titanium (Ti), nickel (Ni), neodymium (Nd), and copper (Cu).

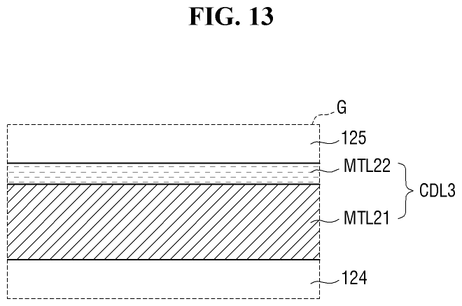

That is, the third conductive layer CDL3 may have a multilayer structure including a second main layer MTL21 (see FIG. 13) made of a metal material having relatively low resistance and a second cover layer MTL22 located on the second main layer MTL21 and made of a different metal material from the second main layer MTL21.

The second cover layer MTL22 may be made of a metal material that can block diffusion of the metal material of the second main layer MTL21 to the surrounding insulating material. For example, the second cover layer MTL22 may include titanium (Ti).

Because the third conductive layer CDL3 includes the second main layer MTL21 having relatively low resistance as described above, it may have lower resistance than the first conductive layer CDL1.

Referring to FIGS. 7, 9 and 10, the first connection electrode CCE1 may be electrically connected to the gate electrode GDT of the driving transistor DT through the first connection contact hole CCH1 and may be electrically connected to the first transistor ST1 and the third transistor ST3 through the second connection contact hole CCH2.

Accordingly, the gate electrode GDT of the driving transistor DT may be electrically connected to the first transistor ST1 and the third transistor ST3 through the first connection electrode CCE1, the first connection contact hole CCH1, and the second connection contact hole CCH2.

A data line DL may be electrically connected to the first electrode S2 of the second transistor ST2 through the third connection contact hole CCH3.

The second connection electrode CCE2 may be electrically connected to the second electrode D32 (see FIG. 8) of the fourth sub-transistor ST32 (see FIG. 8) through the fourth connection contact hole CCH4 and may be electrically connected to the initialization voltage line VIL through the fifth connection contact hole CCH5.

Accordingly, the second electrode D32 (see FIG. 8) of the fourth sub-transistor ST32 (see FIG. 8) may be electrically connected to the initialization voltage line VIL through the second connection electrode CCE2, the fourth connection contact hole CCH4, and the fifth connection contact hole CCH5.

A first power line VDL may be electrically connected to the first electrode S5 (see FIG. 8) of the fifth transistor ST5 through the sixth connection contact hole CCH6.

The anode connection electrode ANDE may be electrically connected to the fourth transistor ST4 and the sixth transistor ST6 through the seventh connection contact hole CCH7.

Referring to FIG. 11, the circuit layer 120 may include the semiconductor layer SEL (CHDT, SDT, DDT, CH2, S2, D2, CH32, S32, D32, CH6, S6 and D6) on the substrate 110, the first conductive layer CDL1 (GWL, GIL, ECL and GDT) which is located on the gate insulating layer 122 covering the semiconductor layer SEL (CHDT, SDT, DDT, CH2, S2, D2, CH32, S32, D32, CH6, S6 and D6) and includes first direction lines (GWL, GIL, ECL and GCL of FIG. 8) extending in the first direction DR1, the second conductive layer CDL2 (VIL and VDAL) which is located on the interlayer insulating layer 123 covering the first conductive layer CDL1 (GWL, GIL, ECL and GDT), the third conductive layer CDL3 (DL, VDL, CCE1, CCE2 and ANDE) which is located on the first planarization layer 124 covering the second conductive layer CDL2 (VIL and VDAL) and includes second direction lines VDRL extending in the second direction DR2, and a second planarization layer 125 which covers the third conductive layer CDL3 (DL, VDL, CCE1, CCE2 and ANDE).

The circuit layer 120 may further include a buffer layer 121 located between the substrate 110 and the semiconductor layer SEL (CHDT, SDT, DDT, CH2, S2, D2, CH32, S32, D32, CH6, S6 and D6).

Each of the buffer layer 121, the gate insulating layer 122, and the interlayer insulating layer 123 may be made of at least one inorganic layer. For example, each of the buffer layer 121, the gate insulating layer 122, and the interlayer insulating layer 123 may be a multilayer in which one or more inorganic layers selected from silicon nitride, silicon oxynitride, silicon oxide, titanium oxide, and aluminum oxide are alternately stacked.

Each of the first planarization layer 124 and the second planarization layer 125 may be made of an organic layer such as acryl resin, epoxy resin, phenolic resin, polyamide resin, or polyimide resin.

The light emitting element layer 130 may be located on the second planarization layer 125 of the circuit layer 120.

The light emitting element layer 130 may include an anode 131 located on the circuit layer 120 and corresponding to each of the emission areas EA, a pixel defining layer 132 located on the circuit layer 120, corresponding to the non-emission area NEA around each of the emission areas EA and covering edges of the anode 131, a first common layer 133 located on the anode 131, a light emitting layer 134 located on the first common layer 133, a second common layer 135 located on the pixel defining layer 132 and the light emitting layer 134, and a cathode 136 located on the second common layer 135.

The second common layer 135 located on the pixel defining layer 132 and the light emitting layer 134 and the cathode 136 located on the second common layer 135 may correspond to the display area DA including the emission areas EA and the non-emission area NEA. That is, the second common layer 135 and the cathode 136 may correspond to the emission areas EA as a whole.

The anode 131 may be located on the second planarization layer 125, may correspond to each of the emission areas EA, and may be electrically connected to the anode connection electrode ANDE through an anode contact hole ANDH penetrating the second planarization layer 125.

Accordingly, the fourth transistor ST4 and the sixth transistor ST6 may be electrically connected to the anode 131 through the anode connection electrode ANDE.

The anode 131 may include a metal material having high reflectivity, such as a stacked structure (Ti/Al/Ti) of aluminum and titanium, a stacked structure (ITO/AVITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer 132 may be located on the second planarization layer 125, may correspond to the non-emission area NEA, and may cover the edges of the anode 131.

The pixel defining layer 132 may be made of an organic layer such as acryl resin, epoxy resin, phenolic resin, polyamide resin, or polyimide resin.

The first common layer 133 may be located on the anode 131 and may correspond to each of the emission areas EA. In each of the emission areas EA, the first common layer 133 may be located between the anode 131 and the light emitting layer 134.

The first common layer 133 may include a hole transport layer made of a hole transporting organic material.

Alternatively, the first common layer 133 may further include a hole injection layer located between the anode 131 and the hole transport layer and made of a hole injecting organic material.

The light emitting layer 134 may be made of an organic light emitting material that converts electron-hole pairs into light.

The organic light emitting material may include a host material and a dopant. The dopant may include a phosphorescent material or a fluorescent material.

For example, the light emitting layer 134 of each first emission area EA1 emitting light of the first color may include a host material of carbazole biphenyl (CBP) or 1,3-bis (carbazol-9-yl) (mCP).

In addition, a dopant of the light emitting layer 134 of each first emission area EA1 may include one or more phosphorescent materials selected from bis(1-phenylisoquinoline)acetylacetonate iridium (PIQIr(acac)), bis(1-phenylquinoline)acetylacetonate iridium (PQIr(acac)), tris (1-phenylquinoline)iridium (PQIr) and octaethylporphyrin platinum (PtOEP) or may be a fluorescent material including PBD:Eu(DBM)3(Phen) or perylene.

The light emitting layer 134 of each second emission area EA2 emitting light of the second color in a wavelength band lower than that of the first color may include a host material of CBP or mCP.

In addition, a dopant of the light emitting layer 134 of the second emission area EA2 may be a phosphorescent material including Ir(ppy)3(fac tris(2-phenylpyridine)iridium) or a fluorescent material including tris(8-hydroxyquinolino)aluminum (Alq3).

The light emitting layer 134 of each third emission area EA3 emitting light of the third color in a wavelength band lower than that of the second color may include a host material of CBP or mCP.

A dopant of the light emitting layer 134 of each third emission area EA3 may be a phosphorescent material including (4,6-F2ppy)2Irpic or L2BD111.

The above description of the organic light emitting material of the light emitting layer 134 is only an example, and the material of the light emitting layer 134 according to some embodiments is not limited to the above description.

The second common layer 135 may be located on the pixel defining layer 132 and the light emitting layer 134 and may correspond to the display area DA including the emission areas EA. In each of the emission areas EA, the second common layer 135 may be located between the light emitting layer 134 and the cathode 136.

The second common layer 135 may include an electron transport layer made of an electron transporting organic material.

Alternatively, the second common layer 135 may further include an electron injection layer located between the electron transport layer and the cathode 136 and made of an electron injecting organic material.

The cathode 136 is located on the second common layer 135. Like the second common layer 135, the cathode 136 may correspond to the display area DA including the emission areas EA.

The cathode 136 may be made of a transparent conductive material (TCO) capable of transmitting light, such as ITO or IZO, or a semi-transmissive conductive material such as magnesium (Mg), silver (Ag) or an alloy of Mg and Ag. When the cathode 136 is made of a semi-transmissive conductive material, an improvement in light output efficiency by a microcavity can be expected.

The light emitting element layer 130 may include light emitting elements LE, each including the anode 131 and the cathode 136 facing each other and the first common layer 133, the light emitting layer 134 and the second common layer 135 interposed between the anode 131 and the cathode 136. The light emitting elements LE may correspond to the emission areas EA, respectively.

The light emitting element layer 130 is covered with the sealing layer 140 located on the light emitting element layer 130.

The sealing layer 140 may include a first inorganic layer 141 covering the light emitting element layer 130 and made of an inorganic insulating material, an organic layer 142 located on the first inorganic layer 141 and made of an organic insulating material, and a second inorganic layer 143 covering the organic layer 142 and made of an inorganic insulating material.

Each of the first inorganic layer 141 and the second inorganic layer 143 may be made of an inorganic insulating material. For example, each of the first inorganic layer 141 and the second inorganic layer 143 may have a structure in which one or more inorganic layers selected from a silicon nitride layer, a silicon oxynitride layer, a silicon oxide layer, a titanium oxide layer, and an aluminum oxide layer are stacked.

The organic layer 142 is located between the first inorganic layer 141 and the second inorganic layer 143. The organic layer 142 may be made of an organic layer such as acryl resin, epoxy resin, phenolic resin, polyamide resin, or polyimide resin.

The relatively thick organic layer 142 made of an organic insulating material may prevent or reduce damage to the light emitting element layer 130 by foreign substances such as dust.

Because the organic layer 142 is located between the first inorganic layer 141 and the second inorganic layer 143, each made of a relatively hydrophobic inorganic insulating material, permeation of oxygen or moisture through the organic layer 142 can be reduced.

FIG. 12 is an enlarged view of the portion F of FIG. 11 according to some embodiments. FIG. 13 is an enlarged view of the portion G of FIG. 11 according to some embodiments.

Referring to FIG. 12, the second conductive layer CDL2 of the circuit layer 120 according to some embodiments may have a structure in which the first main layer MTL11 and the first cover layer MTL12 are stacked.

The first main layer MTL11 may be located on the interlayer insulating layer 123. The first main layer MTL11 may be made of a metal material having relatively low resistance to reduce the RC delay of the wirings (i.e., VIL and VDAL of FIG. 9) made of the second conductive layer CDL2.

The first cover layer MTL12 may be made of a dissimilar metal material having a corrosion potential difference from the metal material of the first main layer MTL11. The first cover layer MTL12 may be made of a metal material that can block diffusion of the metal material of the first main layer MTL11 to the surrounding area.

For example, the first main layer MTL11 may be made of copper (Cu) or aluminum (Al). In this case, the first cover layer MTL12 may be made of titanium (Ti) or molybdenum (Mo). That is, the second conductive layer CDL2 may be a double layer of any one of Cu/Ti, Cu/Mo, Al/Ti, and Al/Mo.

Referring to FIG. 13, the third conductive layer CDL3 of the circuit layer 120 according to some embodiments may have a structure in which the second main layer MTL21 and the second cover layer MTL22 are stacked.

The second main layer MTL21 may be located on the first planarization layer 124. The second main layer MTL21 may be made of a metal material having relatively low resistance to reduce the RC delay of the wirings (i.e., DL and VDL of FIG. 10) made of the third conductive layer CDL3.

The second cover layer MTL22 may be made of a dissimilar metal material having a corrosion potential difference from the metal material of the second main layer MTL21. The second cover layer MTL22 may be made of a metal material that can block diffusion of the metal material of the second main layer MTL21 to the surrounding area.

For example, the second main layer MTL21 may be made of copper (Cu) or aluminum (Al). In this case, the second cover layer MTL22 may be made of titanium (Ti) or molybdenum (Mo). That is, the third conductive layer CDL3 may be a double layer of any one of Cu/Ti, Cu/Mo, Al/Ti, and Al/Mo.

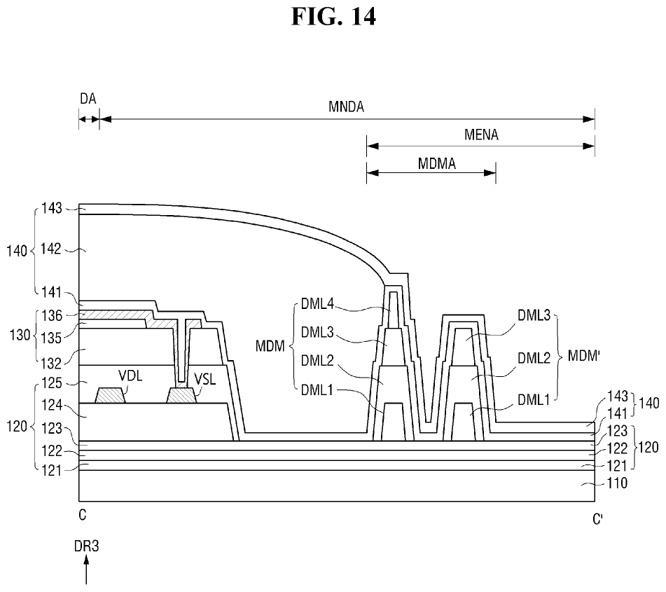

FIG. 14 is a cross-sectional view taken along the line C-C′ of FIG. 4 according to some embodiments.

Referring to FIG. 14, the substrate 110 of the display device 10 according to some embodiments may include the main non-display area MNDA arranged around the display area DA.

As illustrated in FIG. 4, the main non-display area MNDA may surround the display area DA.

As illustrated in FIG. 14, the main non-display area MNDA may include a main encapsulation area MENA adjacent to edges of the substrate 110. In addition, the main encapsulation area MENA may include a main dam area MDMA adjacent to the display area DA. The main encapsulation area MENA and the main dam area MDMA may surround the display area DA.

The display device 10 according to some embodiments may include a main dam portion MDM and MDM′ located in the main dam area MDMA of the main non-display area MNDA.

The main dam portion MDM and MDM′ may include one or more main dams MDM and MDM′ sequentially surrounding the edges of the display area DA.

One main dam MDM among the one or more main dams MDM and MDM′ may have a structure in which two or more dam layers DML1 through DML4 are stacked. The two or more dam layers DML1 through DML4 may be made of the same layer as two or more of the first planarization layer 124, the second planarization layer 125, and the pixel defining layer 132, respectively.

In addition, an uppermost layer (i.e., a fourth dam layer DML4) among the two or more dam layers DML1 through DML4 may be made of the same layer as spacers, which are located on the pixel defining layer 132, correspond to a portion of the non-emission area NEA, and are spaced apart from each other. The spacers are designed to support a mask provided in the process of placing the first common layer 133 and the light emitting layer 134. The spacers may reduce damage to the anode 131 and the pixel defining layer 132 as well as the first common layer 133 and the light emitting layer 134.

For example, one main dam MDM among the one or more main dams MDM and MDM′ may include a first dam layer DML1 located on the interlayer insulating layer 123 and made of the same layer as the first planarization layer 124, a second dam layer DML2 located on the first dam layer DML1 and made of the same layer as the second planarization layer 125, a third dam layer DML3 located on the second dam layer DML2 and made of the same layer as the pixel defining layer 132, and the fourth dam layer DML4 located on the third dam layer DML3 and made of the same layer as the spacers.

In addition, the other main dam MDM′ among the one or more main dams MDM and MDM′ may include a first dam layer DML1 located on the interlayer insulating layer 123 and made of the same layer as the first planarization layer 124, a second dam layer DML2 located on the first dam layer DML1 and made of the same layer as the second planarization layer 125, and a third dam layer DML3 located on the second dam layer DML2 and made of the same layer as the pixel defining layer 132.

However, the above description is only an example, and the structure of the main dam portion MDM and MDM′ according to some embodiments is not limited to the illustration of FIG. 14.

The main dam portion MDM and MDM′ is designed to limit the range in which the organic layer 142 of the sealing layer 140 is located. That is, the organic layer 142 is located within the area surrounded by the main dam portion MDM and MDM′ and does not extend to the edges of the substrate 110.

The first inorganic layer 141 and the second inorganic layer 143 of the sealing layer 140 extend to the main encapsulation area MENA of the main non-display area MNDA and cover the main dam portion MDM and MDM′. For example, the first inorganic layer 141 and the second inorganic layer 143 may extend to the edges of the substrate 110.

Because connection wirings, each made of at least one of the first conductive layer CDL1, the second conductive layer CDL2 and the third conductive layer CDL3, are located in the main non-display area MNDA, the first planarization layer 124, the second planarization layer 125 and the pixel defining layer 132 may extend to a portion of the main non-display area MNDA adjacent to the display area DA.

However, because the first planarization layer 124, the second planarization layer 125 and the pixel defining layer 132 are made of an organic insulating material, an oxygen or moisture permeation path may be easily generated. Therefore, the first planarization layer 124, the second planarization layer 125 and the pixel defining layer 132 may not extend over the entire main non-display area MNDA and may be spaced apart from the main dam area MDMA. Accordingly, a valley in which the interlayer insulating layer 123 is exposed may be formed in a portion where the first planarization layer 124, the second planarization layer 125 and the pixel defining layer 132 are spaced apart from the main dam portion MDM and MDM′ and in a portion between the one or more main dams MDM and MDM′.

In addition, because the first planarization layer 124, the second planarization layer 125 and the pixel defining layer 132 do not extend to the edges of the substrate 110, the interlayer insulating layer 123 may also be exposed in an area between the main dam area MDMA in the main encapsulation area MENA of the main non-display area MNDA and the edges of the substrate 110.

Therefore, the first inorganic layer 141 may contact the interlayer insulating layer 123 exposed in the valleys of the main non-display area MNDA and in a portion of the main encapsulation area MENA. In addition, the second inorganic layer 143 may contact the first inorganic layer 141 in the main encapsulation area MENA. Accordingly, a sealing structure formed by bonding of inorganic materials may be provided in the main non-display area MNDA.

Therefore, the generation of the oxygen or moisture permeation path at the edges of the substrate 110 may be blocked or delayed.

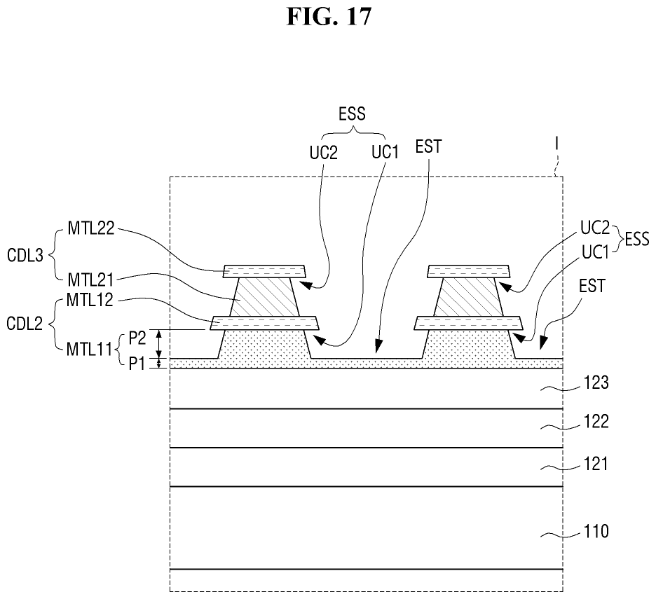

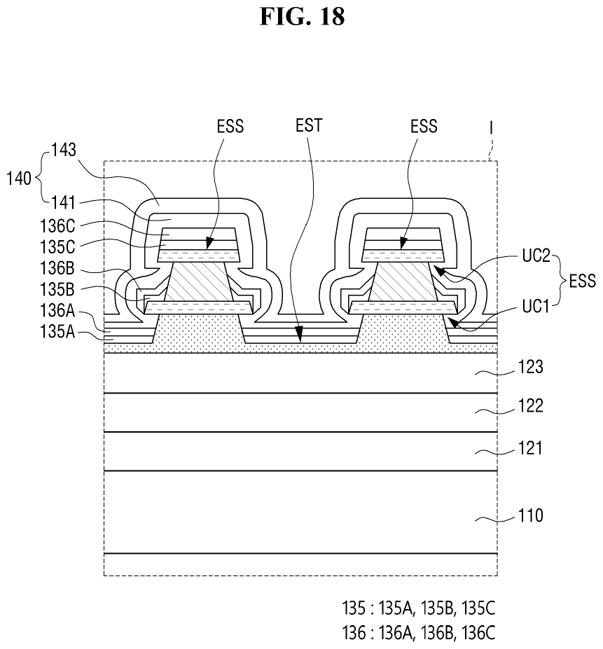

FIG. 15 is a layout view of the portion D of FIG. 4 according to some embodiments. FIG. 16 is a cross-sectional view taken along the line H-H′ of FIG. 15 according to some embodiments. FIG. 17 is an enlarged view of sealing auxiliary structures ESS and etch stop portions EST in portion I of FIG. 16. FIG. 18 is an enlarged view of the portion I of FIG. 16.

Referring to FIG. 15, the substrate 110 of the display device 10 according to some embodiments includes the display area DA, the hole area HLA surrounded by the display area DA, and the additional non-display area ANDA between the display area DA and the hole area HLA.

The display device 10 according to some embodiments includes the sealing auxiliary structures ESS located in the additional non-display area ANDA and sequentially surrounding the hole area HLA.

Referring to FIG. 16, the additional non-display area ANDA of the substrate 110 of the display device 10 according to some embodiments may include a sub-encapsulation area SENA adjacent to the rim of the hole area HLA and surrounding the hole area HLA and a wiring bypass area LSSA adjacent to the display area DA and surrounding the sub-encapsulation area SENA.

In addition, the display device 10 according to some embodiments includes the through portion THM corresponding to the hole area HLA and penetrating at least the substrate 110. That is, the through portion THM may penetrate a portion of the display device 10 which corresponds to the hole area HLA. For example, the through portion THM may penetrate a portion of each of the substrate 110, the buffer layer 121, the gate insulating layer 122, the interlayer insulating layer 123, the first inorganic layer 141, and the second inorganic layer 143.

As illustrated in FIG. 15, the circuit layer 120 of the display device 10 according to some embodiments includes the pixel drivers PXD respectively corresponding to the emission areas EA arranged in the display area DA.

In addition, the circuit layer 120 of the display device 10 according to some embodiments may further include the wirings SL, DL, VDL and VIAL electrically connected to the pixel drivers PXD.

For example, the circuit layer 120 may include scan lines SL (GWL, GIL, GCL and ECL) extending in the first direction DR1 and electrically connected to the pixel drivers PXD and second direction lines VDRL extending in the second direction DR2 and electrically connected to the pixel drivers PXD.

The scan lines SL may include the scan write lines GWL, the scan initialization lines GIL, the emission control lines ECL, and the gate control lines GCL.

The second direction lines VDRL may include the data lines DL, the first power lines VDL, and the initialization voltage auxiliary lines VIAL.

In addition, some wirings intersecting the hole area HLA and the additional non-display area ANDA among the wirings SL, DL, VDL and VIAL of the circuit layer 120 may bypass the hole area HLA along the rim of the hole area HLA in the wiring bypass area LSSA of the additional non-display area ANDA.

The second direction lines VDRL may include hole intersecting lines HINL intersecting the hole area HLA and the additional non-display area ANDA. Each of the hole intersecting lines HINL among the second direction lines VDRL may include a bypass wiring portion DEP located in the wiring bypass area LSSA and bypassing the hole area HLA along the rim of the hole area HLA.

That is, the data lines DL may include first hole intersecting lines HINL1 intersecting the hole area HLA and the additional non-display area ANDA and general data lines DL′ other than the first hole intersecting lines HINL1.

The first power lines VDL may include second hole intersecting lines HINL2 intersecting the hole area HLA and the additional non-display area ANDA and general first power lines VDL′ other than the second hole intersecting lines HINL2.

In addition, the initialization voltage auxiliary lines VIAL may include third hole intersecting lines HINL3 intersecting the hole area HLA and the additional non-display area ANDA and general initialization voltage auxiliary lines VIAL′ other than the third hole intersecting lines HINL3.

As illustrated in FIG. 16, the bypass wiring portion DEP of each of the hole intersecting lines HINL may be made of the third conductive layer CDL3 on the first planarization layer 124, like the second direction lines VDRL (DL, VDL and VIAL).

In addition, a bypass wiring portion of each of the scan lines SL located in the wiring bypass area LSSA may be made of the second conductive layer CDL2 on the interlayer insulating layer 123, like the scan lines SL.

According to some embodiments, the second conductive layer CDL2 may have a stacked structure of the first main layer MTL11 and the first cover layer MTL12, and the third conductive layer CDL3 may have a stacked structure of the second main layer MTL21 and the second cover layer MTL22.

In addition, the display device 10 according to some embodiments may further include a sub-dam portion SDM and SDM′ located in a sub-dam area SDMA of the sub-encapsulation area SENA which is relatively adjacent to the wiring bypass area LSSA.

The sub-dam portion SDM and SDM′ may include one or more sub-dams SDM and SDM′ sequentially surrounding the hole area HLA.

Like the one or more main dams MDM and MDM′, the one or more sub-dams SDM and SDM′ may have a structure in which two or more dam layers DML1 through DML4 are stacked. The two or more dam layers DML1 through DML4 may be made of the same layer as two or more of the first planarization layer 124, the second planarization layer 125, and the pixel defining layer 132, respectively.

In addition, an uppermost layer (i.e., a fourth dam layer DML4) among the two or more dam layers DML1 through DML4 may be made of the same layer as spacers which are located on the pixel defining layer 132, correspond to a portion of the non-emission area NEA and are spaced apart from each other.

That is, one sub-dam SDM among the one or more sub-dams SDM and SDM′ may include a first dam layer DML1 located on the interlayer insulating layer 123 and made of the same layer as the first planarization layer 124, a second dam layer DML2 located on the first dam layer DML1 and made of the same layer as the second planarization layer 125, a third dam layer DML3 located on the second dam layer DML2 and made of the same layer as the pixel defining layer 132, and the fourth dam layer DML4 located on the third dam layer DML3 and made of the same layer as the spacers.

The other sub-dam SDM′ among the one or more sub-dams SDM and SDM′ may include a first dam layer DML1 located on the interlayer insulating layer 123 and made of the same layer as the first planarization layer 124, a second dam layer DML2 located on the first dam layer DML1 and made of the same layer as the second planarization layer 125, and a third dam layer DML3 located on the second dam layer DML2 and made of the same layer as the pixel defining layer 132.

However, the above description is only an example, and the structure of the sub-dam portion SDM and SDM′ according to some embodiments is not limited to the illustration of FIG. 16.

Because the bypass wiring portions of the second direction lines VDRL and the bypass wiring portions of the scan lines SL are located in the wiring bypass area LSSA, the first planarization layer 124, the second planarization layer 125 and the pixel defining layer 132 may extend to the wiring bypass area LSSA.

However, because the first planarization layer 124, the second planarization layer 125 and the pixel defining layer 132 are made of an organic insulating material, an oxygen or moisture permeation path may be easily generated. Therefore, the first planarization layer 124, the second planarization layer 125 and the pixel defining layer 132 may not extend to the through portion THM of the hole area HLA and may be spaced apart from the sub-dam area SDMA. Accordingly, a valley in which the interlayer insulating layer 123 is exposed may be formed in a portion where the first planarization layer 124, the second planarization layer 125 and the pixel defining layer 132 are spaced apart from the sub-dam portion SDM and SDM′ and in a portion between the one or more sub-dams SDM and SDM′.

In addition, because the first planarization layer 124, the second planarization layer 125 and the pixel defining layer 132 do not extend to the through portion THM of the hole area HLA, the interlayer insulating layer 123 may also be exposed in an area between the sub-dam area SDMA in the sub-encapsulation area SENA of the additional non-display area ANDA and the through portion THM.

Accordingly, the sealing auxiliary structures ESS of the sub-encapsulation area SENA may be located on the interlayer insulating layer 123.

The display device 10 according to some embodiments includes the sealing auxiliary structures ESS located in the additional non-display area ANDA and sequentially surrounding the hole area HLA.

Referring to FIG. 17, each of the sealing auxiliary structures ESS of the display device 10 according to some embodiments includes the first main layer MTL11, the first cover layer MTL12 on the first main layer MTL11, the second main layer MTL21 on the first cover layer MTL12, the second cover layer MTL22 on the second main layer MTL21, a first undercut portion UC1 in which the first cover layer MTL12 protrudes from the first main layer MTL11, and a second undercut portion UC2 in which the second cover layer MTL22 protrudes from the second main layer MTL21.

That is, each of the auxiliary sealing structures ESS may include the first main layer MTL11 and the first cover layer MTL12 of the second conductive layer CDL2 and the second main layer MTL21 and the second cover layer MTL22 of the third conductive layer CDL3.

The first undercut portion UC1 and the second undercut portion UC2 are designed to separate the second common layer 135 and the cathode 136. Therefore, a width of the first undercut portion UC1 and a width of the second undercut portion UC2 may be determined to be equal to or greater than a predetermined minimum threshold value in consideration of the thickness, deposition strength, adhesion, and cohesion of each of the second common layer 135 and the cathode 136.

In addition, the width of the first undercut portion UC1 and the width of the second undercut portion UC2 may be determined to be equal to or less than a predetermined maximum threshold value in consideration of the thickness and strength of each of the first cover layer MTL12 and the second cover layer MTL22 and the width of each of the first main layer MTL11 and the second main layer MTL21. For example, the width of the first undercut portion UC1 and the width of the second undercut portion UC2 may be determined in consideration of whether the protruding shape of each of the first cover layer MTL12 and the second cover layer MTL22 can be maintained.

The width of the first undercut portion UC1 refers to a width by which the first cover layer MTL12 protrudes from the first main layer MTL11.

The width of the second undercut portion UC2 refers to a width by which the second cover layer MTL22 protrudes from the second main layer MTL21.

For example, each of the width of the first undercut portion UC1 and the width of the second undercut portion UC2 may be within the range of 0.2 to 0.3 μm.

In addition, because the first main layer MTL11 and the first cover layer MTL12 corresponding to the first undercut portion UC1 in each of the sealing auxiliary structures ESS support the second main layer MTL21, the width of the first undercut portion UC1 may be smaller than the width of the second undercut portion UC2.

For example, the width of the second undercut portion UC2 may be 0.3 μm or less, and the width of the first undercut portion UC1 may be 0.25 μm or less.

In addition, the display device 10 according to some embodiments may further include an etch stop portion EST located in an area between the sealing auxiliary structures ESS.

Like the sealing auxiliary structures ESS, the etch stop portion EST may be located on the interlayer insulating layer 123.

As illustrated in FIG. 17, according to some embodiments, the etch stop portion EST may be made of a portion P1 of the first main layer MTL11.

That is, the etch stop portion EST may be made of a first portion P1 of the first main layer MTL11 which has a predetermined thickness and is located between the sealing auxiliary structures ESS.

The etch stop portion EST remains on the interlayer insulating layer 123 between the sealing auxiliary structures ESS to block the exposure of the interlayer insulating layer 123. Therefore, damage to the interlayer insulating layer 123 can be prevented or reduced in a process of providing the first undercut portion UC1 and the second undercut portion UC2.

In addition, the first main layer MTL11 of the sub-encapsulation area SENA may further include a second portion P2 located on the first portion P1, and the second portion P2 may be provided in each of the sealing auxiliary structures ESS or may be removed to expose the etch stop portion EST.

Referring to FIG. 18, the second common layer 135 and the cathode 136 corresponding to the entire display area DA are formed or arranged without a separate mask process. Therefore, they may also extend to the hole area HLA and the additional non-display area ANDA surrounded by the display area DA.

However, the display device 10 according to some embodiments includes the sealing auxiliary structures ESS located in the additional non-display area ANDA and each including the first undercut portion UC1 and the second undercut portion UC2.

Therefore, the second common layer 135 and the cathode 136 located in the additional non-display area ANDA may be separated by the first undercut portion UC1 and the second undercut portion UC2 of each of the sealing auxiliary structures ESS.

That is, the second common layer 135 of the additional non-display area ANDA may include a first layer separation portion 135A located on the interlayer insulating layer 123 and the etch stop portion EST, a second layer separation portion 135B located on side surfaces of the first cover layer MTL12 and the second main layer MTL21, and a third layer separation portion 135C located on the second cover layer MTL22.

In addition, the cathode 136 of the additional non-display area ANDA may include a first electrode separation portion 136A located on the interlayer insulating layer 123 and the etch stop portion EST, a second electrode separation portion 136B located on the side surfaces of the first cover layer MTL12 and the second main layer MTL21, and a third electrode separation portion 136C located on the second cover layer MTL22.

Because the second common layer 135 of an organic material and the cathode 136 of a metal material are separated by each of the sealing auxiliary structures ESS as described above, the generation of the oxygen or moisture permeation path using the organic material and the metal material can be blocked.

For example, according to some embodiments, because each of the sealing auxiliary structures ESS includes the first undercut portion UC1 and the second undercut portion UC2, the second common layer 135 and the cathode 136 are separated twice by each of the sealing auxiliary structures ESS. Therefore, the generation of the oxygen or moisture permeation path can be more securely blocked.

In addition, because the second common layer 135 and the cathode 136 are separated by the first undercut portion UC1 and the second undercut portion UC2 of each of the sealing auxiliary structures ESS in the additional non-display area ANDA, a portion of each of the sealing auxiliary structures ESS may be exposed without being covered with the second common layer 135 and the cathode 136.

That is, a portion of the first main layer MTL11 adjacent to the first cover layer MTL12 in the additional non-display area ANDA may be exposed by the first undercut portion UC1 without being covered with the second common layer 135 and the cathode 136 and may contact the first inorganic layer 141.

In addition, a portion of the second main layer MTL21 adjacent to the second cover layer MTL22 in the additional non-display area ANDA may be exposed by the second undercut portion UC2 without being covered with the second common layer 135 and the cathode 136 and may contact the first inorganic layer 141.

In other words, in the sub-encapsulation area SENA of the additional non-display area ANDA, the first inorganic layer 141 of the sealing layer 140 may contact a portion of the first main layer MTL11 and a portion of the second main layer MTL21 respectively exposed by the first undercut portion UC1 and the second undercut portion UC2 without being covered with the second common layer 135 and the cathode 136.

Therefore, even if a separate mask process is excluded from the process of placing the second common layer 135 and the cathode 136, a sealing structure formed by bonding of inorganic materials may be provided in the sub-encapsulation area SENA of the additional non-display area ANDA.

Therefore, the generation of the oxygen or moisture permeation path around the through portion THM may be blocked or delayed. Accordingly, even if the through portion THM is included, a reduction in quality reliability and life of the display device 10 can be prevented or reduced.

Next, display devices 10 of other embodiments will be described.

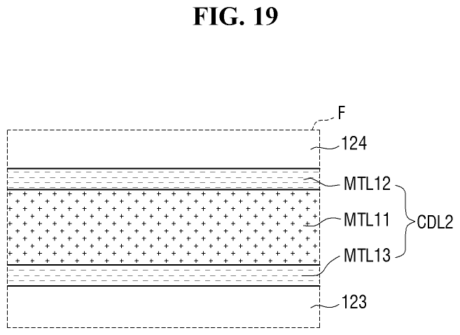

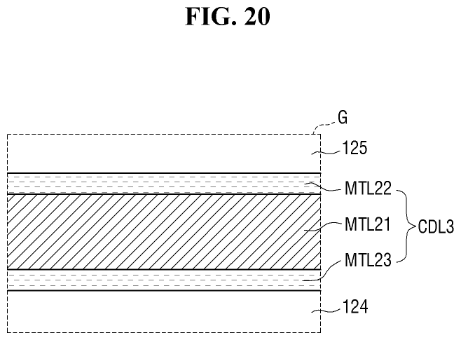

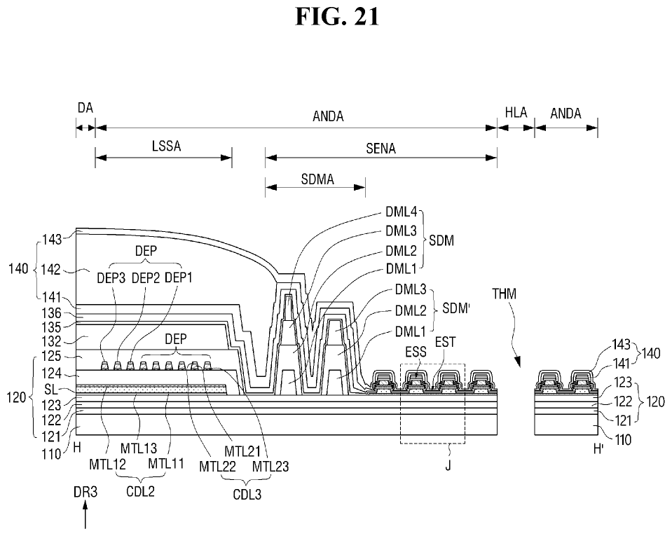

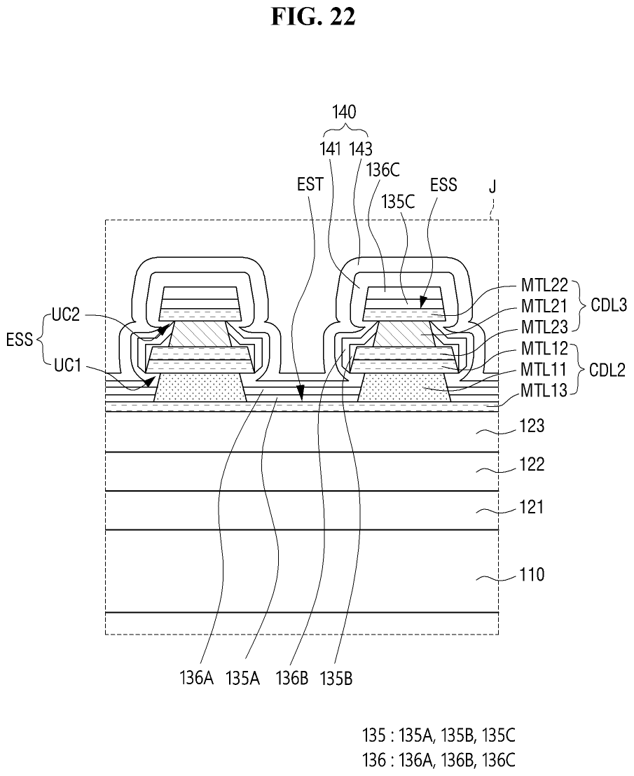

FIG. 19 is an enlarged view of the portion F of FIG. 11 according to some embodiments. FIG. 20 is an enlarged view of the portion G of FIG. 11 according to some embodiments. FIG. 21 is a cross-sectional view taken along the line H-H′ of FIG. 15 according to some embodiments. FIG. 22 is an enlarged view of the portion J of FIG. 21.

Referring to FIG. 19, a second conductive layer CDL2 of a circuit layer 120 of a display device 10 according to some embodiments is the same as that of the embodiments illustrated in FIG. 12 except that it further includes a first bottom layer MTL13 located between an interlayer insulating layer 123 and a first main layer MTL11. Therefore, some redundant description may be omitted below.

Referring to FIG. 20, a third conductive layer CDL3 of the circuit layer 120 of the display device 10 according to some embodiments is the same as that of the embodiments illustrated in FIG. 13 except that it further includes a second bottom layer MTL23 located between a first planarization layer 124 and a second main layer MTL21. Therefore, some redundant description may be omitted below.

Each of the first bottom layer MTL13 and the second bottom layer MTL23 may be made of titanium (Ti) or molybdenum (Mo), like a first cover layer MTL12 and a second cover layer MTL22.

That is, according to some embodiments, each of the second conductive layer CDL2 and the third conductive layer CDL3 may be a triple layer of any one of Ti/Cu/Ti, Ti/Cu/Mo, TI/Al/Ti, Ti/Al/Mo, Mo/Cu/Ti, Mo/Cu/Mo, Mo/Al/Ti, and Mo/Al/Mo.

Referring to FIGS. 21 and 22, the display device 10 according to some embodiments is the same as that of the embodiments illustrated in FIGS. 16 through 18 except that each sealing auxiliary structure ESS further includes the first bottom layer MTL13 and the second bottom layer MTL23 and that the second bottom layer MTL23 of each sealing auxiliary structure ESS is located between the first cover layer MTL12 and the second main layer MTL21. Therefore, some redundant description may be omitted below.

In addition, according to some embodiments, an etch stop portion EST of the display device 10 may include the first bottom layer MTL13.

As described above, according to some embodiments, the second conductive layer CDL2 further includes the first bottom layer MTL13, and the third conductive layer CDL3 further includes the second bottom layer MTL23. Therefore, diffusion of the metal material of the first main layer MTL11 and the second main layer MTL21 toward a substrate 110 may be prevented or reduced.

In addition, because the second conductive layer CDL2 further includes the first bottom layer MTL13, even if the first main layer MTL11 is completely etched in an area between the sealing auxiliary structures ESS in the process of providing a first undercut portion UC1 and a second undercut portion UC2, the first bottom layer MTL13 may remain. Therefore, the etch stop portion EST between the sealing auxiliary structures ESS may be relatively easily made of the first bottom layer MTL13.

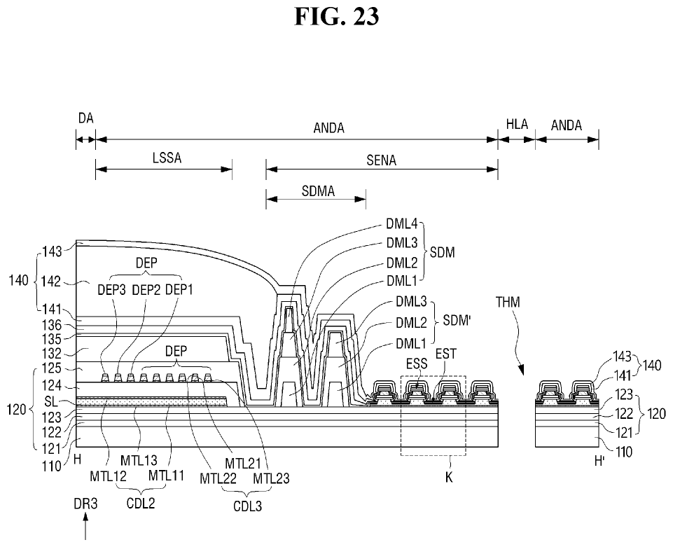

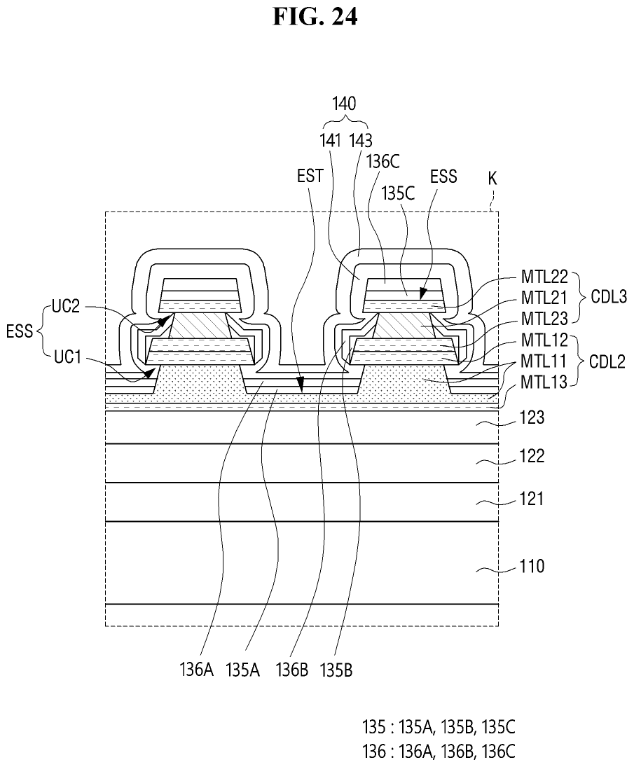

FIG. 23 is a cross-sectional view taken along the line H-H′ of FIG. 15 according to some embodiments. FIG. 24 is an enlarged view of the portion K of FIG. 23.

Referring to FIGS. 23 and 24, a display device 10 according to some embodiments is the same as that of the embodiments illustrated in FIGS. 21 and 22 except that an etch stop portion EST further includes a portion of a first main layer MTL11 located on a first bottom layer MTL13. Therefore, some redundant description may be omitted below.

As described above, according to some embodiments, the etch stop portion EST includes the first bottom layer MTL13 and a first portion P1 (see FIG. 17) of the first main layer MTL11. Therefore, an interlayer insulating layer 123 can be more securely protected.

Next, a method of manufacturing a display device according to some embodiments will be described.

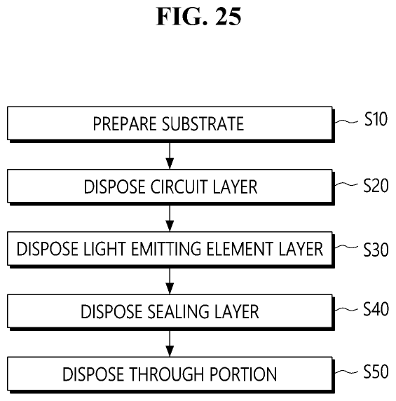

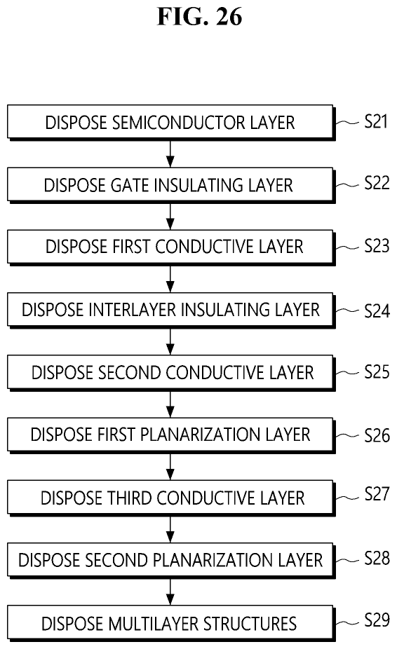

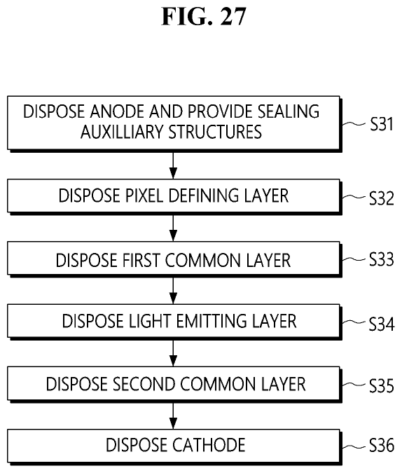

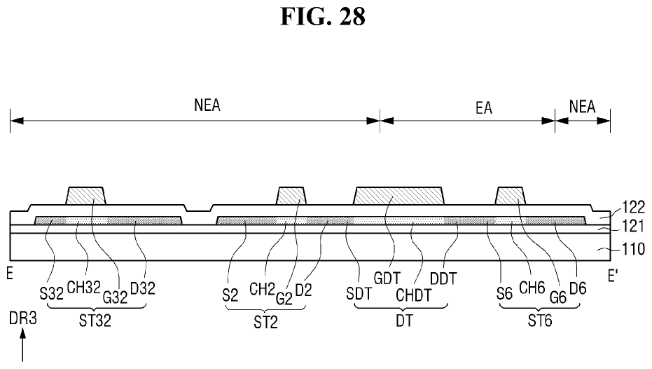

FIG. 25 is a flowchart illustrating a method of manufacturing a display device according to some embodiments. FIG. 26 is a flowchart illustrating an operation of placing a circuit layer in FIG. 25. FIG. 27 is a flowchart illustrating an operation of placing a light emitting element layer in FIG. 25. FIGS. 28 through 45 are process diagrams showing the operations illustrated in FIGS. 25, 26 and 27.

Referring to FIG. 25, the method of manufacturing the display device according to some embodiments includes preparing a substrate 110 including a display area DA in which emission areas EA are arranged, a main non-display area MNDA arranged around the display area DA, a hole area HLA surrounded by the display area DA, and an additional non-display area ANDA between the hole area HLA and the display area DA (operation S10), placing a circuit layer 120, which includes pixel drivers PXD respectively corresponding to the emission areas EA, on the substrate 110 (operation S20), and placing a light emitting element layer 130, which includes light emitting elements LE respectively corresponding to the emission areas EA, on the circuit layer 120 (operation S30).

In addition, the method of manufacturing the display device according to some embodiments may further include, after the placing of the light emitting element layer 130 (operation S30), placing a sealing layer 140 on the light emitting element layer 130 (operation S40) and placing a through portion THM corresponding to the hole area HLA and penetrating at least the substrate 110 (operation S50).

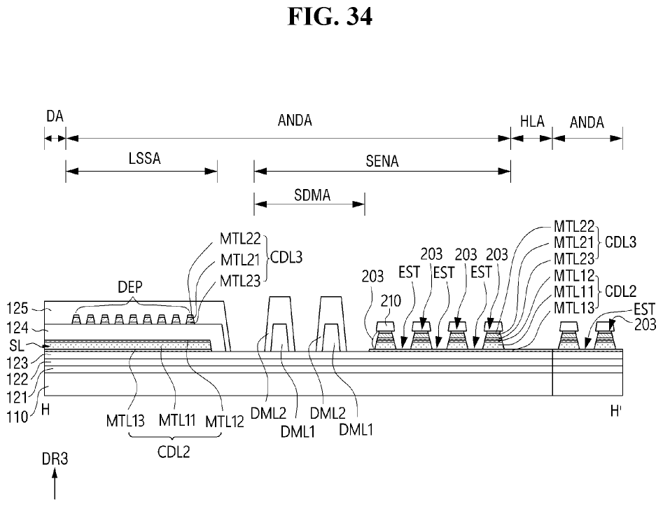

Referring to FIG. 26, the placing of the circuit layer 120 (operation S20) includes placing a semiconductor layer SEL on the substrate 110 (operation S21), placing a gate insulating layer 122, which covers the semiconductor layer SEL, on the substrate 110 (operation S22), placing a first conductive layer CDL1 on the gate insulating layer 122 (operation S23), placing an interlayer insulating layer 123, which covers the first conductive layer CDL1, on the gate insulating layer 122 (operation S24), placing a second conductive layer CDL2 including a first main layer MTL11 and a first cover layer MTL12 sequentially stacked on the interlayer insulating layer 123 (operation S25), placing a first planarization layer 124, which corresponds to the display area DA and covers the second conductive layer CDL2, on the interlayer insulating layer 123 (operation S26), placing a third conductive layer CDL3 including a second main layer MTL21 and a second cover layer MTL22 sequentially stacked on the first planarization layer 124 (operation S27), placing a second planarization layer 125, which corresponds to the display area DA and covers the third conductive layer CDL3, on the first planarization layer 124 (operation S28), and placing, in the additional non-display area ANDA, multilayer structures 203 (see FIG. 34), each including the first main layer MTL11 and the first cover layer MTL12 and the second main layer MTL21 and the second cover layer MTL22 on the first cover layer MTL12 and sequentially surrounding the hole area HLA (operation S29).

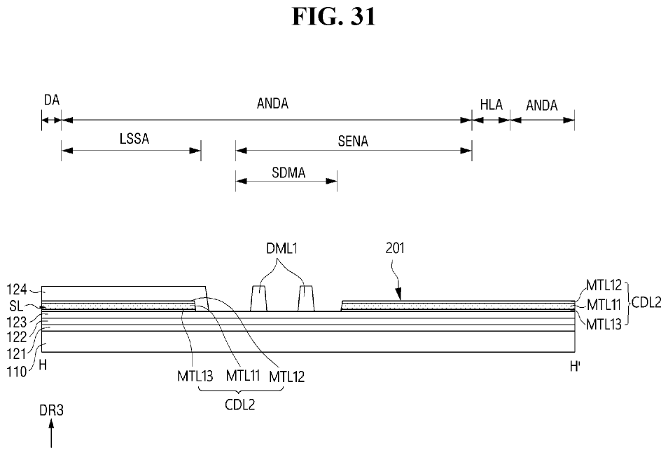

In the placing of the second conductive layer CDL2 (operation S25), a first auxiliary material layer 201 (see FIG. 31) located in a portion of the additional non-display area ANDA and including the first main layer MTL11 and the first cover layer MTL12 is provided.

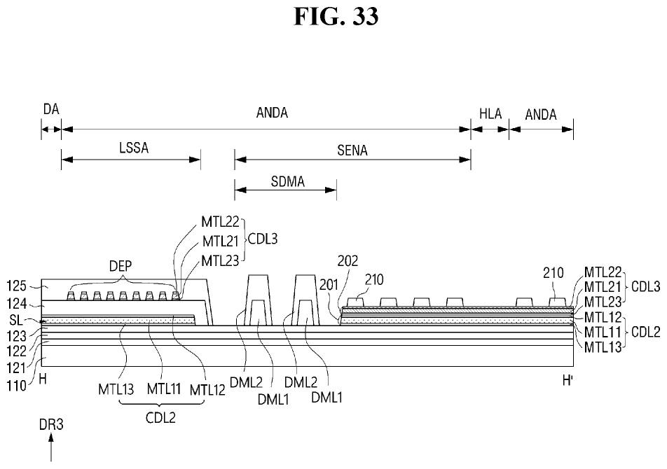

In the placing of the third conductive layer CDL3 (operation S27), a second auxiliary material layer 202 (see FIG. 33) located on the first auxiliary material layer 201 and including the second main layer MTL21 and the second cover layer MTL22 is provided.

In addition, the placing of the multilayer structures 203 (operation S29) includes a process of partially removing the first auxiliary material layer 201 and the second auxiliary material layer 202. Accordingly, the multilayer structures 203 sequentially surrounding the hole area HLA and each including the first main layer MTL11, the first cover layer MTL12, the second main layer MTL21 and the second cover layer MTL22 stacked sequentially may be provided.

Referring to FIG. 27, the placing of the light emitting element layer 130 (operation S30) includes placing an anode 131, which corresponds to each of the emission areas EA, on the second planarization layer 125 (operation S31).

In the placing of the anode 131 (operation S31), side surfaces of at least a portion P2 (see FIG. 17) of the first main layer MTL11 and side surfaces of the second main layer MTL21 of each of the multilayer structures 203 in the additional non-display area ANDA are partially removed. Accordingly, the multilayer structures 203 are transformed into sealing auxiliary structures ESS. Here, each of the sealing auxiliary structure ESS includes a first undercut portion UC1 and a second undercut portion UC2. The first undercut portion UC1 has a structure in which the first cover layer MTL12 protrudes from the first main layer MTL11. The second undercut portion UC2 has a structure in which the second cover layer MTL22 protrudes from the second main layer MTL21.

In addition, the placing of the light emitting element layer 130 (operation S30) may further include placing a pixel defining layer 132, which corresponds to a non-emission area NEA around each of the emission areas EA and covers edges of the anode 131, on the second planarization layer 125 (operation S32), placing a first common layer 133 on the anode 131 (operation S33), placing a light emitting layer 134 on the first common layer 133 (operation S34), placing a second common layer 135, which corresponds to the display area DA, on the pixel defining layer 132 and the light emitting layer 134 (operation S35), and placing a cathode 136, which corresponds to the display area DA, on the second common layer 135 (operation S36).

Referring to FIG. 28, the substrate 110 including the display area DA in which the emission areas EA are arranged is provided (operation S10).

A buffer layer 121 may be placed by applying an inorganic insulating material onto the substrate 110.

The buffer layer 121 may correspond to the entire area MA and SBA of the substrate 110. That is, the buffer layer 121 may extend to edges of the substrate 110.

The buffer layer 121 may be a multilayer in which one or more inorganic layers selected from silicon nitride, silicon oxynitride, silicon oxide, titanium oxide, and aluminum oxide are alternately stacked.

The semiconductor layer SEL (CHDT, SDT, DDT, CH2, S2, D2, CH32, S32, D32, CH6, S6 and 06) may be placed on the buffer layer 121 by partially removing a semiconductor material stacked on the buffer layer 121 (operation S21).

The semiconductor layer SEL may be made of any one of polysilicon, amorphous silicon, and an oxide semiconductor.

The gate insulating layer 122 may be placed by applying an inorganic insulating material, which covers the semiconductor layer SEL, onto the buffer layer 121 (operation S22).

The gate insulating layer 122 may correspond to the entire area MA and SBA of the substrate 110. That is, the gate insulating layer 122 may extend to the edges of the substrate 110.

The gate insulating layer 122 may be a multilayer in which one or more inorganic layers selected from silicon nitride, silicon oxynitride, silicon oxide, titanium oxide, and aluminum oxide are alternately stacked.

The first conductive layer CDL1 (GDT, GWL, GIL, ECL and GCL) may be placed on the gate insulating layer 122 by partially removing a conductive material stacked on the gate insulating layer 122 (operation S23).

Here, the semiconductor layer SEL excluding portions overlapping the first conductive layer CDL1, that is, excluding channels CH11, CH12, CH2, CH31, CH32, CH4, CH5, CH6 of transistors DT and ST1 through ST6 may be made conductive.

The first conductive layer CDL1 may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

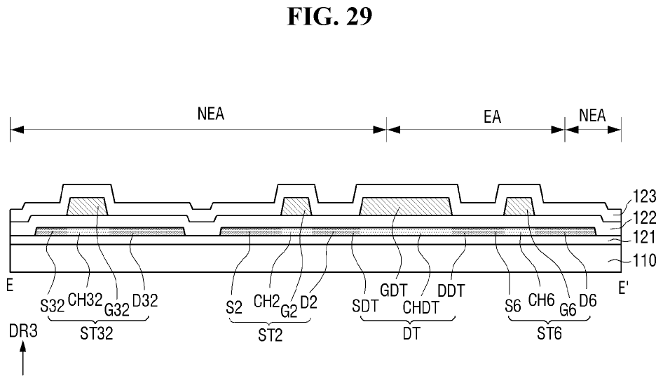

Referring to FIG. 29, the interlayer insulating layer 123 may be placed by applying an inorganic insulating material, which covers the first conductive layer CDL1 (GDT, GWL, GIL, ECL and GCL), onto the gate insulating layer 122 (operation S24).

The interlayer insulating layer 123 may correspond to the entire area MA and SBA of the substrate 110. That is, the interlayer insulating layer 123 may extend to the edges of the substrate 110.

The interlayer insulating layer 123 may be a multilayer in which one or more inorganic layers selected from silicon nitride, silicon oxynitride, silicon oxide, titanium oxide, and aluminum oxide are alternately stacked.

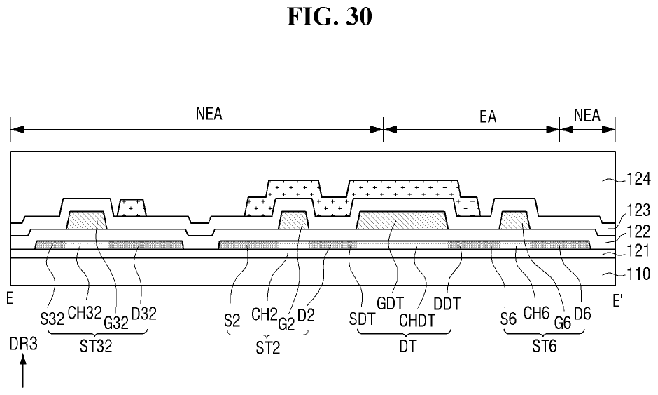

Referring to FIG. 30, the second conductive layer CDL2 (VIL and VDAL) may be placed on the interlayer insulating layer 123 by partially removing a conductive material on the interlayer insulating layer 123 (operation S25).

The second conductive layer CDL2 may have a double-layer structure including the first main layer MTL11 made of a metal material having relatively low resistance and the first cover layer MTL12 located on the first main layer MTL11 and made of a metal material different from that of the first main layer MTL11.

Alternatively, the second conductive layer CDL2 may have a triple-layer structure further including a first bottom layer MTL13 located between the interlayer insulating layer 123 and the first main layer MTL11.

Referring to FIG. 31, in the placing of the second conductive layer CDL2 (operation S25), the first auxiliary material layer 201 located in the hole area HLA and a portion of the additional non-display area ANDA adjacent to the hole area HLA and including the first main layer MTL11 and the first cover layer MTL12 may be provided.

That is, the second conductive layer CDL2 further includes the first auxiliary material layer 201 located in the hole area HLA and a portion of the additional non-display area ANDA.

Next, the first planarization layer 124 may be placed by applying an organic insulating material, which covers the second conductive layer CDL2, onto the interlayer insulating layer 123 (operation S26).

The first planarization layer 124 may correspond to the display area DA. In addition, the first planarization layer 124 may extend to a portion of the main non-display area MNDA and a portion of the additional non-display area ANDA.

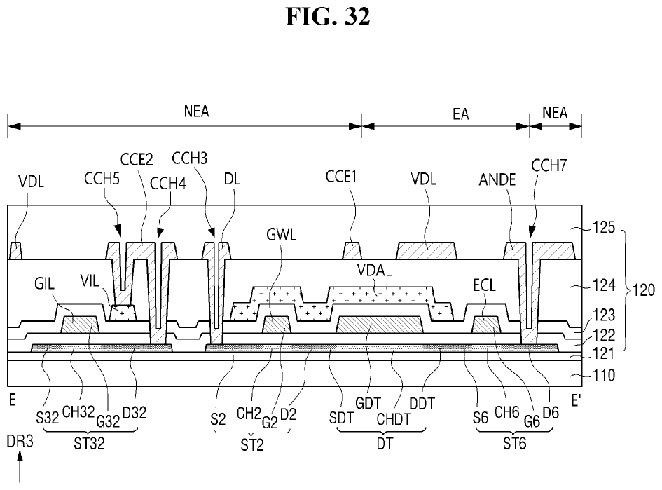

Next, the first planarization layer 124 may be partially removed to form contact holes (e.g., CCH4 and CCH7 of FIG. 32) penetrating the first planarization layer 124.

Here, first dam layers DML1 may be placed in a main dam area MDMA and a sub-dam area SDMA.

As illustrated in FIG. 31, the first planarization layer 124 is spaced apart from the first dam layers DML1.

Accordingly, as illustrated in FIGS. 14 and 16, a valley in which the interlayer insulating layer 123 is exposed may be located in an area between the first planarization layer 124 and a first dam layer DML1 and in an area between the first dam layers DML1. In addition, the interlayer insulating layer 123 may be exposed in an area between a first dam layer DML1 and the edges of the substrate 110.

The first planarization layer 124 may be made of an organic layer such as acryl resin, epoxy resin, phenolic resin, polyamide resin, or polyimide resin.

Referring to FIG. 32, the third conductive layer CDL3 (DL, VDL, CCE1, CCE2 and ANDE) may be placed on the first planarization layer 124 by partially removing a conductive material on the first planarization layer 124 (operation S27).

The third conductive layer CDL3 may have a double-layer structure including the second main layer MTL21 made of a metal material having relatively low resistance and the second cover layer MTL22 located on the second main layer MTL21 and made of a metal material different from that of the second main layer MTL21.

Alternatively, the third conductive layer CDL3 may have a triple-layer structure further including a second bottom layer MTL23 located between the first planarization layer 124 and the second main layer MTL21.

Referring to FIG. 33, in the placing of the third conductive layer CDL3 (operation S27), the second auxiliary material layer 202 located on the first auxiliary material layer 201 and including the second main layer MTL21 and the second cover layer MTL22 may be provided.

That is, the third conductive layer CDL3 further includes the second auxiliary material layer 202 located in the hole area HLA and a portion of the additional non-display area ANDA.

Next, the second planarization layer 125 may be placed by applying an organic insulating material, which covers the third conductive layer CDL3, onto the first planarization layer 124 (operation S28).

The second planarization layer 125 may correspond to the display area DA. In addition, the second planarization layer 125 may extend to a portion of the main non-display area MNDA and a portion of the additional non-display area ANDA.

Accordingly, the circuit layer 120 may be provided.

Next, the second planarization layer 125 may be partially removed to form an anode contact hole ANDH penetrating the second planarization layer 125.

Here, second dam layers DML2 may be placed on the first dam layers DML1 of each of the main dam area MDMA and the sub-dam area SDMA.

The second planarization layer 125 is spaced apart from the second dam layers DML2.

Accordingly, as illustrated in FIGS. 14 and 16, a valley in which the interlayer insulating layer 123 is exposed may be located in an area between the second planarization layer 125 and a second dam layer DML2 and in an area between the second dam layers DML2. In addition, the interlayer insulating layer 123 may be exposed in an area between a second dam layer DML2 and the edges of the substrate 110.

The second planarization layer 125 may be made of an organic layer such as acryl resin, epoxy resin, phenolic resin, polyamide resin, or polyimide resin.

Referring to FIGS. 33 and 34, in a state where masks 210 are arranged in the additional non-display area ANDA to sequentially surround the hole area HLA, the first auxiliary material layer 201 and the second auxiliary material layer 202 are partially removed together to form the multilayer structures 203 (operation S29).

Here, an etch stop portion EST corresponding to an area between the multilayer structures 203 may be further formed.

The etch stop portion EST may include the first bottom layer MTL13.

Alternatively, the etch stop portion EST may include the first bottom layer MTL13 and a portion of the first main layer MTL11.

Alternatively, the etch stop portion EST may include a portion of the first main layer MTL11 on the interlayer insulating layer 123.

The masks 210 for placing the multilayer structures 203 may be provided in the process of placing the second dam layers DML2. That is, the masks 210 may be the same layer as the second planarization layer 125.

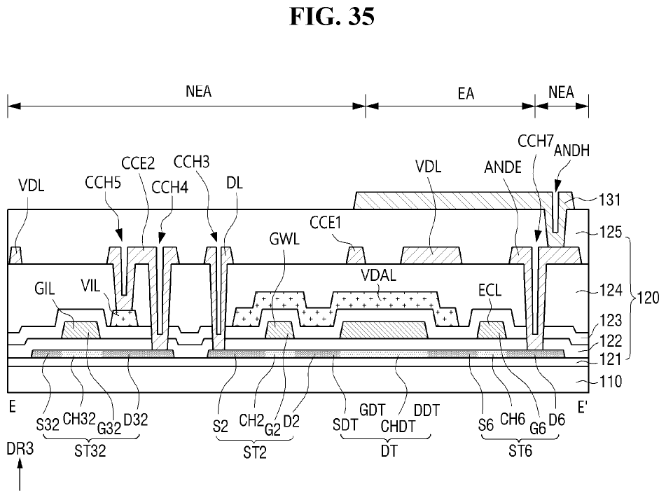

Referring to FIG. 35, a conductive material on the second planarization layer 125 may be partially removed to provide the anode 131, which corresponds to each of the emission areas EA, on the second planarization layer 125 (operation S31).

The anode 131 may be electrically connected to each of the pixel drivers PXD of the circuit layer 120 through the anode contact hole ANDH penetrating the second planarization layer 125.

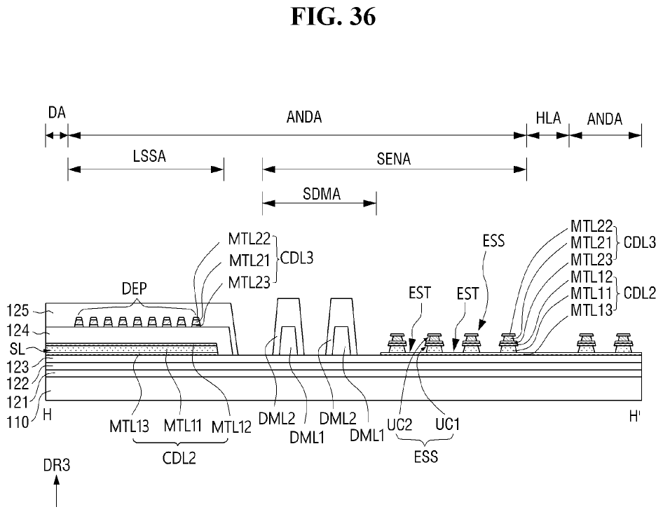

Referring to FIG. 36, in the placing of the anode 131 (operation S31), in each of the multilayer structures 203 located in the additional non-display area ANDA, side surfaces of at least a portion of the first main layer MTL11 and side surfaces of the second main layer MTL21 may be partially etched by being exposed to an etching material for placing the anode 131.

Accordingly, the multilayer structures 203 may be transformed into the sealing auxiliary structures ESS, each including the first undercut portion UC1 and the second undercut portion UC2.

The first undercut portion UC1 may be provided by a structure in which the first cover layer MTL12 protrudes from the first main layer MTL11.

The second undercut portion UC2 may be provided by a structure in which the second cover layer MTL22 protrudes from the second main layer MTL21.

In addition, because a portion of the interlayer insulating layer 123 which corresponds to an area between the multilayer structures 203 is protected by the etch stop portion EST, it may not be exposed to the etching material for placing the anode 131. Accordingly, damage to the interlayer insulating layer 123 in the area between the sealing auxiliary structures ESS may be prevented or reduced. This may enable relatively improved sealing.

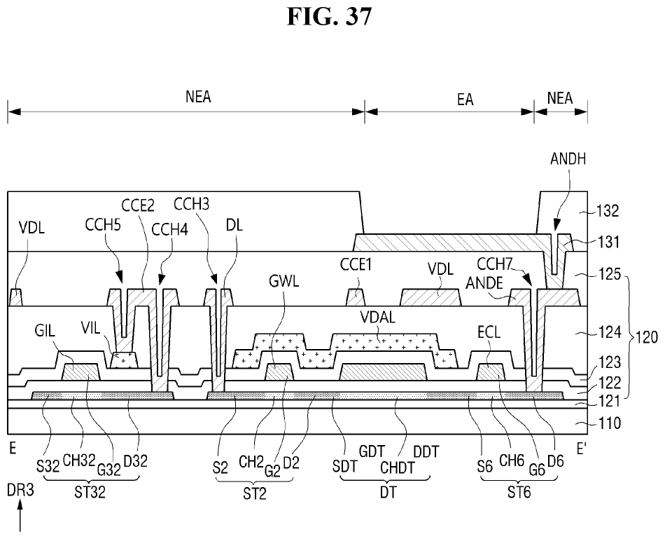

Referring to FIG. 37, the pixel defining layer 132 which corresponds to the non-emission area NEA and covers the edges of the anode 131 may be placed by partially removing an organic insulating material applied onto the second planarization layer 125 (operation S32).

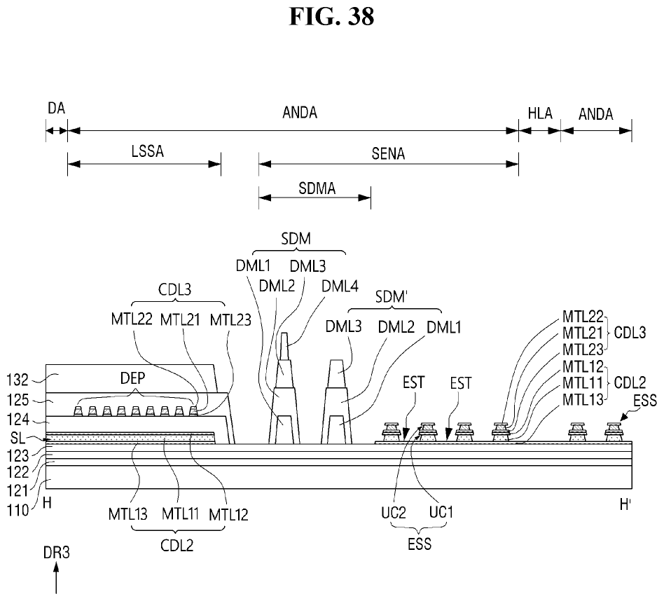

Referring to FIG. 38, in the placing of the pixel defining layer 132 (operation S32), third dam layers DML3 may be placed on the second dam layers DML2 in each of the main non-display area MNDA and the additional non-display area ANDA.

In addition, according to some embodiments, when spacers are provided on a portion of the pixel defining layer 132 by the same mask process as that for the pixel defining layer 132, a fourth dam layer DML4 may be placed on at least a portion of each third dam layer DML3, together with the third dam layer DML3.

Accordingly, a main dam portion MDM and MDM′ and a sub-dam portion SDM and SDM′ may be provided.

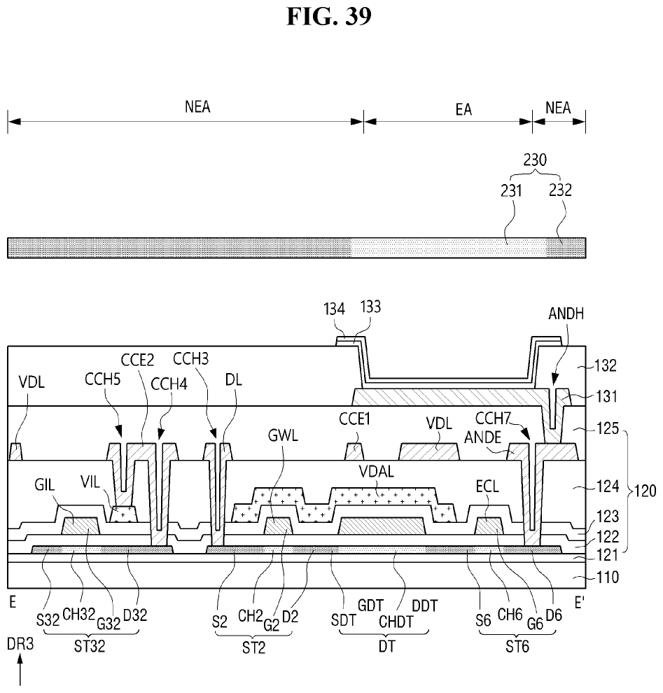

Referring to FIG. 39, an organic material is printed in a state where a deposition mask 230 including transmitting portions 231 respectively corresponding to the emission areas EA and a blocking portion 232 corresponding to the non-emission area NEA is aligned. Accordingly, the first common layer 133 corresponding to each emission area EA may be placed on the anode 131 (operation S33), and the light emitting layer 134 may be placed on the first common layer 133 (operation S34).

Here, the deposition mask 230 may be provided for each of first emission areas EA1, second emission areas EA2, and third emission areas EA3.

That is, the placing of the first common layer 133 and the light emitting layer 134 (operations S33 and S34) may be performed for each color of the emission areas EA.

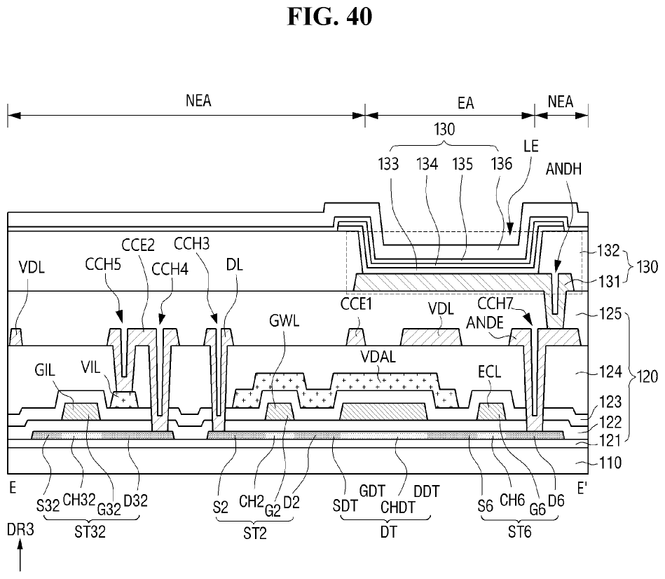

Referring to FIG. 40, the second common layer 135 corresponding to the display area DA may be placed on the pixel defining layer 132 and the light emitting layer 134 (operation S35), and the cathode 136 may be placed on the second common layer 135 (operation S36).

Accordingly, the light emitting element layer 130 may be provided.

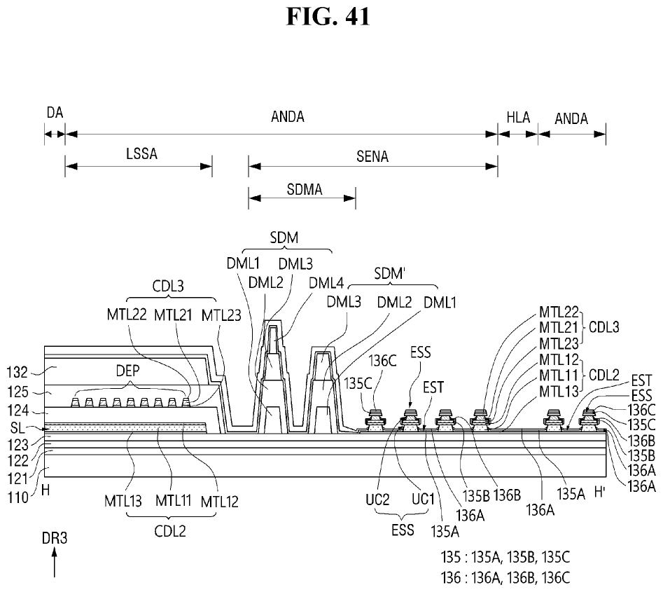

Referring to FIG. 41, the placing of the second common layer 135 (operation S35) and the placing of the cathode 136 (operation S36) may be performed using not a mask corresponding to each emission area EA, but a mask corresponding to at least the entire display area DA. In this case, the second common layer 135 and the cathode 136 are also placed in the hole area HLA and the additional non-display area ANDA surrounded by the display area DA.

However, according to some embodiments, because there are the sealing auxiliary structures ESS provided by the placing of the anode 131 (operation S31), the second common layer 135 and the cathode 136 are separated by the sealing auxiliary structures ESS in the additional non-display area ANDA.

That is, as illustrated in FIGS. 18, 22 and 24, the second common layer 135 of the additional non-display area ANDA may include a first layer separation portion 135A located on the interlayer insulating layer 123 and the etch stop portion EST, a second layer separation portion 135B located on side surfaces of the first cover layer MTL12 and the second main layer MTL21, and a third layer separation portion 135C located on the second cover layer MTL22.

In addition, the cathode 136 of the additional non-display area ANDA may include a first electrode separation portion 136A located on the interlayer insulating layer 123 and the etch stop portion EST, a second electrode separation portion 136B located on the side surfaces of the first cover layer MTL12 and the second main layer MTL21, and a third electrode separation portion 136C located on the second cover layer MTL22.

Next, the sealing layer 140 covering the light emitting element layer 130 is placed (operation S40).

The placing of the sealing layer 140 (operation S40) may include placing a first inorganic layer 141, placing an organic layer 142, and placing a second inorganic layer 143.

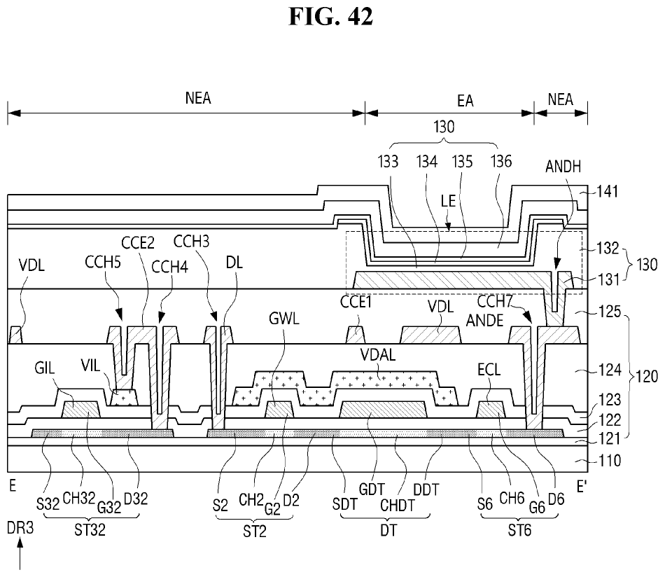

Referring to FIG. 42, the first inorganic layer 141 may be placed by applying an inorganic insulating material onto the cathode 136.

Alternatively, according to some embodiments, the first inorganic layer 141 may be placed on a protective layer of an organic material covering the cathode 136.

The first inorganic layer 141 may extend to the edges of the substrate 110 and may contact the interlayer insulating layer 123 in the main non-display area MNDA and the additional non-display area ANDA.

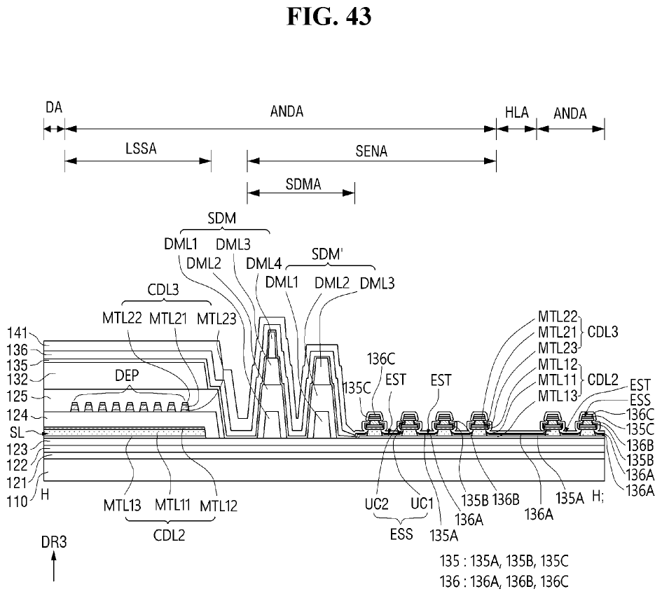

Referring to FIG. 43, the first inorganic layer 141 may contact a portion of the first main layer MTL11 and a portion of the second main layer MTL21 exposed by the first undercut portion UC1 and the second undercut portion UC2 of each of the sealing auxiliary structures ESS.

Accordingly, a bonding structure of the inorganic materials of the interlayer insulating layer 123, the sealing auxiliary structures ESS, and the first inorganic layer 141 may be provided in the main non-display area MNDA and the additional non-display area ANDA.

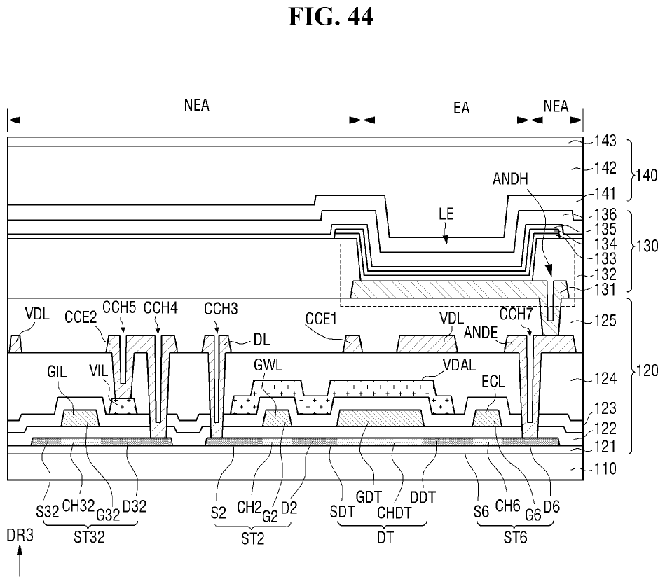

Referring to FIG. 44, the organic layer 142 may be placed in areas defined as the main dam portion MDM and MDM′ and the sub-dam portion SDM and SDM′ by dropping, diffusing, and curing an organic insulating material on the first inorganic layer 141.

In addition, the second inorganic layer 143 may be placed by applying an inorganic insulating material, which covers the organic layer 142, onto the first inorganic layer 141.

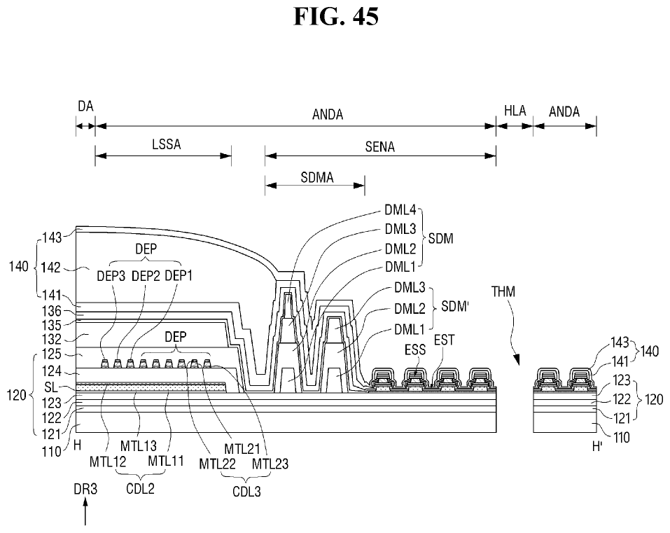

Referring to FIG. 45, the second inorganic layer 143 may extend to the edges of the substrate 110 and may contact the first inorganic layer 141 in the main non-display area MNDA and the additional non-display area ANDA.

Accordingly, a bonding structure of the inorganic materials of the first inorganic layer 141 and the second inorganic layer 143 located on both surfaces of the organic layer 142 may be provided in the main non-display area MNDA and the additional non-display area ANDA.

Next, the through portion THM corresponding to the hole area HLA and penetrating at least the substrate 110 may be provided (operation S50).

The through portion THM may penetrate insulating materials and conductive materials located in the hole area HLA. That is, the through portion THM may penetrate the substrate 110, the buffer layer 121, the gate insulating layer 122, the interlayer insulating layer 123, the etch stop portion EST, the second common layer 135A, the cathode 136A, the first inorganic layer 141 and the second inorganic layer 143 corresponding to the hole area HLA.

As described above, in the method of manufacturing the display device according to some embodiments, the sealing auxiliary structures ESS, each including the first undercut portion UC1 and the second undercut portion UC2, may be provided by the placing of the second conductive layer CDL2 (operation S25), the placing of the third conductive layer CDL3 (operation S27), the placing of the multilayer structures 203 (operation S29), and the placing of the anode 131. Therefore, even if a mask process is not added when the second common layer 135 and the cathode 136 are placed, the second common layer 135 and the cathode 136 may be separated by the sealing auxiliary structures ESS in the additional non-display area ANDA. Hence, despite the exclusion of a separate mask process and the presence of the through portion THM, it is possible to block or delay the generation of an oxygen or moisture permeation path around the through portion THM.

A display device according to some embodiments includes a substrate including a display area, a main non-display area, a hole area and an additional non-display area, a circuit layer on the substrate, a light emitting element layer on the circuit layer, a sealing layer on the light emitting element layer, a through portion located in the hole area and penetrating the substrate, and sealing auxiliary structures located in the additional non-display area between the display area and the hole area and sequentially surrounding the through portion. Each of the sealing auxiliary structures includes a first undercut portion and a second undercut portion. The first undercut portion is provided by a first cover layer protruding from a first main layer. The second undercut portion is provided by a second cover layer protruding from a second main layer located on the first cover layer.

The light emitting element layer may include an anode and a pixel defining layer on the circuit layer, a first common layer on the anode, a light emitting layer on the first common layer, a second common layer on the light emitting layer and the pixel defining layer, and a cathode on the second common layer. The second common layer and the cathode may extend to the additional non-display area and may be separated by the first undercut portion and the second undercut portion of each of the sealing auxiliary structures in the additional non-display area.

The sealing layer may include a first inorganic layer on the light emitting element layer, an organic layer on the first inorganic layer, and a second inorganic layer covering the organic layer.

As described above, according to some embodiments, the second common layer and the cathode extending to the additional non-display area are separated by the first undercut portion and the second undercut portion of each of the sealing auxiliary structures.

Accordingly, the probability that the second common layer and the cathode in the additional non-display area will become an oxygen, contaminant, or moisture permeation path may be reduced.

In addition, a portion of the first main layer may be exposed by the first undercut portion of each of the sealing auxiliary structures without being covered with the second common layer and the cathode extending to the additional non-display area. In addition, a portion of the second main layer may be exposed by the second undercut portion of each of the sealing auxiliary structures without being covered with the second common layer and the cathode extending to the additional non-display area.

Therefore, even if the second common layer and the cathode extend to the additional non-display area due to the exclusion of a separate mask process, the first inorganic layer may contact a portion of the first main layer exposed by the first undercut portion of each of the sealing auxiliary structures and may contact a portion of the second main layer exposed by the second undercut portion of each of the sealing auxiliary structures.

Accordingly, because the first inorganic layer contacts each of the first main layer and the second main layer, a sealing structure formed by bonding between inorganic materials may be provided around the through portion. Therefore, even if a separate mask process is not added, the generation of the oxygen or moisture permeation path around the through portion may be blocked or delayed.

However, the characteristics of embodiments according to the present disclosure are not restricted to the one set forth herein. The above and other characteristics of embodiments according to the present disclosure will become more apparent to one of daily skill in the art to which the present disclosure pertains by referencing the claims, and their equivalents.

What is claimed is:

1. A display device comprising:
a substrate comprising a display area in which emission areas are arranged, a main non-display area around the display area, a hole area surrounded by the display area, and an additional non-display area between the hole area and the display area;
a circuit layer on the substrate and comprising pixel drivers respectively corresponding to the emission areas;
a light emitting element layer on the circuit layer and comprising light emitting elements respectively corresponding to the emission areas;
a sealing layer on the light emitting element layer;
a through portion in the hole area and penetrating at least the substrate; and
sealing auxiliary structures in the additional non-display area and sequentially surrounding the hole area,
wherein each of the sealing auxiliary structures comprises:
a first main layer;
a first cover layer on the first main layer;
a second main layer on the first cover layer;
a second cover layer on the second main layer;
a first undercut portion in which the first cover layer protrudes from the first main layer; and
a second undercut portion in which the second cover layer protrudes from the second main layer.

2. The display device of claim 1, wherein the light emitting element layer comprises:
an anode on the circuit layer and corresponding to each of the emission areas;
a pixel defining layer on the circuit layer, corresponding to a non-emission area around each of the emission areas, and covering edges of the anode;
a first common layer on the anode;
a light emitting layer on the first common layer;
a second common layer on the pixel defining layer and the light emitting layer and corresponding to the display area; and
a cathode on the second common layer and corresponding to the display area,
wherein each of the light emitting elements has a structure in which the light emitting layer is between the anode and the cathode, and
the second common layer and the cathode extend to the additional non-display area and are separated by the first undercut portion and the second undercut portion of each of the sealing auxiliary structures.

3. The display device of claim 2, wherein the circuit layer comprises:
a semiconductor layer on the substrate;
a first conductive layer on a gate insulating layer covering the semiconductor layer;
a second conductive layer on an interlayer insulating layer covering the first conductive layer;
a third conductive layer on a first planarization layer covering the second conductive layer; and
a second planarization covering the third conductive layer,
wherein the second conductive layer comprises the first main layer and the first cover layer, and
the third conductive layer comprises the second main layer and the second cover layer.

4. The display device of claim 3, wherein the additional non-display area comprises:
a sub-encapsulation area adjacent to the hole area and surrounding the hole area; and
a wiring bypass area between the sub-encapsulation area and the display area, and
the circuit layer further comprises wirings electrically connected to the pixel drivers,
wherein some of the wirings intersecting the hole area and the additional non-display area bypass the hole area along edges of the hole area in the wiring bypass area, and
the first planarization layer and the second planarization layer extend to the wiring bypass area.

5. The display device of claim 4, further comprising:
a main dam portion comprising one or more main dams in a main dam area of the main non-display area adjacent to the display area and sequentially surround edges of the display area; and
a sub-dam portion comprising one or more sub-dams in a sub-dam area of the sub-encapsulation area adjacent to the wiring bypass area and sequentially surround the hole area,
wherein the first planarization layer, the second planarization layer, and the pixel defining layer are spaced apart from the main dam area and the sub-dam area.

6. The display device of claim 5, wherein the sealing layer comprises:
a first inorganic layer covering the light emitting element layer and comprising an inorganic insulating material;
an organic layer on the first inorganic layer and comprising an organic insulating material; and
a second inorganic layer covering the organic layer and comprising the inorganic insulating material,
wherein the organic layer corresponds to an area between the main dam portion and the sub-dam portion and overlaps the light emitting element layer, and the first inorganic layer and the second inorganic layer contact each other in the main dam area and the sub-dam area.

7. The display device of claim 6, wherein the first inorganic layer contacts a portion of the first main layer exposed by the first undercut portion of each of the sealing auxiliary structures and contacts a portion of the second main layer exposed by the second undercut portion of each of the sealing auxiliary structures.

8. The display device of claim 5, further comprising an etch stop portion in an area between the sealing auxiliary structures,
wherein the sealing auxiliary structures and the etch stop portion are on the interlayer insulating layer.

9. The display device of claim 8, wherein the etch stop portion comprises a portion of the first main layer on the interlayer insulating layer.

10. The display device of claim 9, wherein each of the first main layer and the second main layer comprises at least one of aluminum (Al) or copper (Cu), and
each of the first cover layer and the second cover layer comprises at least one of titanium (Ti) or molybdenum (Mo).

11. The display device of claim 8, wherein the second conductive layer further comprises a first bottom layer between the interlayer insulating layer and the first main layer,
the third conductive layer further comprises a second bottom layer between the first planarization layer and the second main layer,
each of the sealing auxiliary structures further comprises the first bottom layer and the second bottom layer, and
the second bottom layer of each of the sealing auxiliary structures is between the first cover layer and the second main layer.

12. The display device of claim 11, wherein the etch stop portion comprises the first bottom layer on the interlayer insulating layer.

13. The display device of claim 12, wherein the etch stop portion further comprises a portion of the first main layer on the first bottom layer.

14. The display device of claim 11, wherein each of the first main layer and the second main layer comprises at least one of aluminum (Al) or copper (Cu),
each of the first cover layer and the second cover layer comprises at least one of titanium (Ti) or molybdenum (Mo), and each of the first bottom layer, and
the second bottom layer comprises at least one of titanium (Ti) or molybdenum (Mo).

15. The display device of claim 5, wherein each of the one or more main dams and the one or more sub-dams has a structure in which two or more dam layers are stacked, and
the two or more dam layers comprise a same layer as two or more of the first planarization layer, the second planarization layer and the pixel defining layer, respectively.

16. A method of manufacturing a display device, the method comprising:
preparing a substrate comprising a display area in which emission areas are arranged, a main non-display area around the display area, a hole area surrounded by the display area, and an additional non-display area between the hole area and the display area;
arranging a circuit layer, which comprises pixel drivers respectively corresponding to the emission areas, on the substrate; and
arranging a light emitting element layer, which comprises light emitting elements respectively corresponding to the emission areas, on the circuit layer,
wherein the arranging of the circuit layer comprises:
arranging a semiconductor layer on the substrate;
arranging a gate insulating layer covering the semiconductor layer, on the substrate;
arranging a first conductive layer on the gate insulating layer;
arranging an interlayer insulating layer covering the first conductive layer, on the gate insulating layer;
arranging a second conductive layer comprising a first main layer and a first cover layer sequentially stacked on the interlayer insulating layer;
arranging a first planarization layer corresponding to the display area and covering the second conductive layer, on the interlayer insulating layer;
arranging a third conductive layer comprising a second main layer and a second cover layer sequentially stacked on the first planarization layer;
arranging a second planarization layer corresponding to the display area and covering the third conductive layer, on the first planarization layer; and
arranging, in the additional non-display area, multilayer structures, each comprising the first main layer and the first cover layer and the second main layer and the second cover layer on the first cover layer and sequentially surrounding the hole area, and
the arranging of the light emitting element layer comprises:
arranging an anode corresponding to each of the emission areas, on the second planarization layer,
wherein a first auxiliary material layer is provided in the arranging of the second conductive layer, wherein the first auxiliary material layer is in the hole area and a portion of the additional non-display area and comprises the first main layer and the first cover layer,
a second auxiliary material layer is provided in the arranging of the third conductive layer, wherein the second auxiliary material layer is on the first auxiliary material layer and comprises the second main layer and the second cover layer,
the arranging of the multilayer structures comprises a process of partially removing the first auxiliary material layer and the second auxiliary material layer, and
side surfaces of at least a portion of the first main layer and side surfaces of the second main layer of each of the multilayer structures in the additional non-display area are partially removed in the arranging of the anode, to transform the multilayer structures into sealing auxiliary structures,
wherein each of the multilayer structures comprises a first undercut portion in which the first cover layer protrudes from the first main layer; and a second undercut portion in which the second cover layer protrudes from the second main layer.

17. The method of claim 16, wherein the arranging of the light emitting element layer further comprises:
arranging a pixel defining layer corresponding to a non-emission area around each of the emission areas and covers edges of the anode, on the second planarization layer;
arranging a first common layer on the anode;
arranging a light emitting layer on the first common layer;
arranging a second common layer corresponding to the display area, on the pixel defining layer and the light emitting layer; and
arranging a cathode corresponding to the display area, on the second common layer,
wherein in the arranging of the second common layer, the second common layer extends to the additional non-display area and is separated by the first undercut portion and the second undercut portion of each of the sealing auxiliary structures in the additional non-display area, and
in the arranging of the cathode, the cathode extends to the additional non-display area and is separated by the first undercut portion and the second undercut portion of each of the sealing auxiliary structures in the additional non-display area.

18. The method of claim 17, wherein an etch stop portion corresponding to an area between the multilayer structures is further provided in the arranging of the multilayer structures.

19. The method of claim 18, wherein the etch stop portion comprises another portion of the first main layer.

20. The method of claim 18, wherein the second conductive layer further comprises a first bottom layer between the interlayer insulating layer and the first main layer in the arranging of the second conductive layer,
the third conductive layer further comprises a second bottom layer between the first planarization layer and the second main layer in the arranging of the third conductive layer, and
the second bottom layer of the second auxiliary material layer is on the first cover layer of the first auxiliary material layer.

21. The method of claim 20, wherein the etch stop portion comprises the first bottom layer.

22. The method of claim 21, wherein the etch stop portion further comprises another portion of the first main layer.

23. The method of claim 17, further comprising, after the arranging of the light emitting element layer:
arranging a sealing layer on the light emitting element layer; and
arranging a through portion corresponding to the hole area and penetrating at least the substrate,
wherein the arranging of the sealing layer comprises:
arranging a first inorganic layer covering the light emitting element layer by stacking an inorganic insulating material on the light emitting element layer;
arranging an organic layer comprising an organic insulating material and corresponds to the display area, on the first inorganic layer; and
arranging a second inorganic layer covering the organic layer by stacking the inorganic insulating material on the organic layer,
wherein in the arranging of the first inorganic layer, the first inorganic layer contacts a portion of the first main layer exposed by the first undercut portion of each of the sealing auxiliary structures and contacts a portion of the second main layer exposed by the second undercut portion of each of the sealing auxiliary structures.
